(19) United States
(12) Patent Application Publication
(10) Pub. No.: US 2024/0213357 A1
(43) Pub. Date: Jun. 27, 2024

(54) SEMICONDUCTOR DEVICE AND METHOD OF MANUFACTURING THE SAME

(71) Applicant: Renesas Electronics Corporation, Tokyo (JP)

(72) Inventors: Tomohiro IMAI, Tokyo (JP); Yoshito NAKAZAWA, Tokyo (JP)

(21) Appl. No.: 18/391,388

(22) Filed: Dec. 20, 2023

(30) Foreign Application Priority Data
Dec. 23, 2022 (JP) 2022-206230

(51) Int. Cl. H01L 29/739; H01L 29/06; H01L 29/417; H01L 29/66

(52) U.S. Cl. CPC H01L 29/7397; H01L 29/0696; H01L 29/41708; H01L 29/66348

(57) ABSTRACT

Performance of a semiconductor device is enhanced. A floating region covers a bottom surface of a trench in an active cell. In addition, the floating region covers a bottom surface of a trench in an inactive cell so as to reach a semiconductor substrate between a pair of trenches in the inactive cell. A distance between a base region and the floating region in the inactive cell is smaller than a distance between the base region and the floating region in the active cell.

### CROSS-REFERENCE TO RELATED APPLICATIONS

The disclosure of Japanese Patent Application No. 2022-206230 filed on Dec. 23, 2022 including the specification, drawings and abstract is incorporated herein by reference in its entirety.

### BACKGROUND

The present invention relates to a semiconductor device and a method of manufacturing the same, and particularly, relates to a semiconductor device provided with a gate electrode formed in a trench and a method of manufacturing the same.

In recent years, a semiconductor device including a power semiconductor element such as an insulated gate bipolar transistor (IGBT) has been widely used. In addition, as an IGBT having a low on-resistance, an IGBT adopting a structure in which a gate electrode is buried in the trench has been known.

There are disclosed techniques listed below.

[Patent Document 1] Japanese Unexamined Patent Application Publication No. 2013-140885

[Patent Document 2] Japanese Unexamined Patent Application Publication No. 2017-157733

For example, Patent Document 1 discloses an IGBT having a GGEE structure using an injection enhancement (IE) effect. The IE effect is a technique for enhancing a concentration of charges accumulated in a drift region by causing positive holes to hardly be discharged to an emitter electrode side when an IGBT is in an on-state.

Note that “G” in the GGEE structure represents a structure in which a gate electrode connected to a gate potential is buried in a trench, and is referred to as a gate trench. In addition, “E” in the GGEE structure represents a structure in which a gate electrode connected to an emitter potential is buried in a trench, and is referred to as an emitter trench. Hence, the GGEE structure is a structure in which a pair of emitter trenches is formed at a position apart from a pair of gate trenches to a certain degree.

As disclosed in Patent Document 1 as well, in order to use the IE effect, in a semiconductor substrate between a pair of gate trenches and a pair of emitter trenches, a p-type floating region is formed. This p-type floating region is formed so as to have a depth deeper than that of each of the pair of gate trenches and the pair of emitter trenches. In addition, an n-type hole barrier region having an impurity concentration higher than that of the drift region is formed in the semiconductor substrate sandwiched between the pair of gate trenches and in the semiconductor substrate sandwiched between the pair of emitter trenches.

In addition, Patent Document 2 discloses an IGBT having a GGEEs structure in which a cell pitch of the GGEE structure is shrunk. In the GGEEs structure, a distance between the pair of emitter trenches is set to be smaller than that between the pair of gate trenches. Specifically, “s” of the GGEEs structure represents that the distance between the pair of emitter trenches is shrunk.

### SUMMARY

In a transient state at a time of switching operation of the IGBT, excessive positive holes are likely to be accumulated in the p-type floating region. Hence, in the transient state, uncontrollable potential fluctuation occurs in the p-type floating region, and this potential fluctuation becomes a source of noise generation, causing reduction in performance of the IGBT.

Patent Documents 1 and 2 disclose use of a parasitic PMOS transistor in order to discharge excessive positive holes in the p-type floating region. The parasitic PMOS transistor has a p-type floating region as a source, an n-type hole barrier region as a channel, and a p-type base region as a drain.

When positive holes are injected into the p-type floating region, the potential of the source increases, so that a minus potential difference occurs between the gate electrode and the source. As a result, the parasitic PMOS transistor turns on, and the positive holes in the p-type floating region is discharged to the drain.

This parasitic PMOS transistor is formed in both the pair of gate trenches and the pair of emitter trenches. Here, the inventors of the present application have studied on the IGBT in terms of robustness in a short circuit withstand test using a short circuit, a reverse bias safe operating area (RBSOA), and the like. As a result, the inventors of the present application have found that, if a hole current flowing in the parasitic PMOS transistor of the pair of emitter trenches is allowed to be increased and a hole current flowing in the parasitic PMOS transistor of the pair of gate trenches is allowed to be decreased, the robustness can be enhanced.

A main object of the present application is to enhance the robustness in a short circuit, RBSOA, and the like, thereby enhancing performance of a semiconductor device having such an IGBT. Other objects and novel features of the present invention will be apparent from the description of the present specification and the accompanying drawings.

Of embodiments disclosed in the present application, the typical ones of the inventions disclosed in the present application will briefly be described as follows.

A semiconductor device according to one embodiment includes: a semiconductor substrate of a first conductivity type having an upper surface and a lower surface; a first trench, a second trench, a third trench, and a fourth trench which are formed in the semiconductor substrate on the upper surface side of the semiconductor substrate; a first gate electrode formed in the first trench with a first gate insulating film interposed between the first gate electrode and the first trench; a second gate electrode formed in the second trench with a second gate insulating film interposed between the second gate electrode and the second trench; a third gate electrode formed in the third trench with a third gate insulating film interposed between the third gate electrode and the third trench; a fourth gate electrode formed in the fourth trench with a fourth gate insulating film interposed between the fourth gate electrode and the fourth trench; a first hole barrier region of the first conductivity type formed in the semiconductor substrate between the first trench and the second trench on the upper surface side of the semiconductor substrate; a first base region of a second conductivity type which is an opposite conductivity type to the first conductivity type, the first base region being formed in the first hole barrier region; an emitter region of the first conductivity type formed in the first base region; a second hole barrier region of the first conductivity type formed in the semiconductor substrate between the third trench and the fourth trench on the upper surface side of the semiconductor substrate; a second base region of the second conductivity type formed in the second hole barrier region; and a first floating region of the second conductivity type formed in the semiconductor substrate between the second trench and the third trench on the upper surface side of the semiconductor substrate. The first floating region covers a second bottom surface of the second trench, and covers a third bottom surface of the third trench so as to reach the semiconductor substrate between the third trench and the fourth trench, and a first distance between the second base region and the first floating region is smaller than a second distance between the first base region and the first floating region.

A method of manufacturing a semiconductor device according to one embodiment, includes: (a) preparing a semiconductor substrate of a first conductivity type having an upper surface and a lower surface; (b) forming a first hole barrier region of the first conductivity type and a second hole barrier region of the first conductivity type in the semiconductor substrate, on the upper surface side of the semiconductor substrate; (c) forming a first floating region of a second conductivity type which is an opposite conductivity type to the first conductivity type, in the semiconductor substrate, on the upper surface side of the semiconductor substrate; (d) forming a first trench, a second trench, a third trench, and a fourth trench in the semiconductor substrate, on the upper surface side of the semiconductor substrate; (e) after the (d), forming a first gate insulating film in the first trench, a second gate insulating film in the second trench, a third gate insulating film in the third trench, and a fourth gate insulating film in the fourth trench; (f) after the (e), forming a first gate electrode in the first trench with the first gate insulating film interposed between the first gate electrode and the first trench, a second gate electrode in the second trench with the second gate insulating film interposed between the second gate electrode and the second trench, a third gate electrode in the third trench with the third gate insulating film interposed between the third gate electrode and the third trench, and a fourth gate electrode in the fourth trench with the fourth gate insulating film interposed between the fourth gate electrode and the fourth trench; (g) after the (f), forming a first base region of the second conductivity type in the first hole barrier region, and a second base region of the second conductivity type in the second hole barrier region; and (h) after the (g), forming an emitter region of the first conductivity type in the first base region. The first trench has a first side surface, a second side surface that is opposed to the first side surface, and a first bottom surface connecting the first side surface to the second side surface, the second trench has a third side surface, a fourth side surface that is opposed to the third side surface, and a second bottom surface connecting the third side surface to the fourth side surface, the third trench has a fifth side surface, a sixth side surface that is opposed to the fifth side surface, and a third bottom surface connecting the fifth side surface to the sixth side surface, the fourth trench has a seventh side surface, an eighth side surface that is opposed to the seventh side surface, and a fourth bottom surface connecting the seventh side surface to the eighth side surface, the first trench and the second trench are provided to be spaced apart from each other such that the second side surface and the third side surface are adjacent to each other, the third trench and the fourth trench are provided to be spaced apart from each other such that the sixth side surface and the seventh side surface are adjacent to each other, the first hole barrier region is formed in the semiconductor substrate between the second side surface and the third side surface, the second hole barrier region is formed in the semiconductor substrate between the sixth side surface and the seventh side surface, the first floating region is formed in the semiconductor substrate between the fourth side surface and the fifth side surface, covers the second bottom surface, and covers the third bottom surface so as to extend beyond the sixth side surface, and a first distance between the second base region and the first floating region is shorter than a second distance between the first base region and the first floating region.

According to one embodiment, the performance of the semiconductor device can be enhanced.

### BRIEF DESCRIPTION OF THE DRAWINGS

FIG. 1 is a plan view showing a semiconductor device according to a first embodiment.

FIG. 2 is a plan view showing a main part of the semiconductor device according to the first embodiment.

FIG. 3 is a cross-sectional view of the semiconductor device according to the first embodiment.

FIG. 4 is a cross-sectional view showing a main part of the semiconductor device according to the first embodiment.

FIG. 5 is experimental data resulting from experiment conducted by the inventors of the present application.

FIG. 6 is experimental data resulting from experiment conducted by the inventors of the present application.

FIG. 7 is a cross-sectional view indicating a manufacturing process of the semiconductor device according to the first embodiment.

FIG. 8 is a cross-sectional view indicating the manufacturing process continued from FIG. 7.

FIG. 9 is a cross-sectional view indicating the manufacturing process continued from FIG. 8.

FIG. 10 is a cross-sectional view indicating the manufacturing process continued from FIG. 9.

FIG. 11 is a cross-sectional view indicating the manufacturing process continued from FIG. 10.

FIG. 12 is a cross-sectional view indicating the manufacturing process continued from FIG. 11.

FIG. 13 is a cross-sectional view indicating the manufacturing process continued from FIG. 12.

FIG. 14 is a cross-sectional view indicating the manufacturing process continued from FIG. 13.

FIG. 15 is a cross-sectional view indicating the manufacturing process continued from FIG. 14.

FIG. 16 is a cross-sectional view indicating the manufacturing process continued from FIG. 15.

FIG. 17 is a cross-sectional view showing a semiconductor device according to a second embodiment.

FIG. 18 is a cross-sectional view indicating a manufacturing process of the semiconductor device according to the second embodiment.

FIG. 19 is a cross-sectional view indicating the manufacturing process continued from FIG. 18.

FIG. 20 is a cross-sectional view indicating the manufacturing process continued from FIG. 19.

FIG. 21 is a cross-sectional view showing a GGEEs structure and a GGEE structure.

FIG. 22 is a cross-sectional view indicating a manufacturing process of a semiconductor device according to a third embodiment.

FIG. 23 is a cross-sectional view showing a main part of a semiconductor device according to a study example.

FIG. 24 is a cross-sectional view indicating a manufacturing process of the semiconductor device according to the study example.

FIG. 25 is a cross-sectional view indicating the manufacturing process continued from FIG. 24.

### DETAILED DESCRIPTION

Embodiments of the present application will be described below in detail with reference to the attached drawings. Note that components having the same function are denoted by the same reference symbols throughout the drawings for describing the embodiments, and the repetitive description thereof is omitted. In addition, the description of the same or similar portions is not repeated in principle unless particularly required in the following embodiments.

In addition, an X direction, a Y direction, and a Z direction described in the present application intersect with and orthogonal to each other. In the present application, the Z direction is used as a vertical direction, a height direction, or a thickness direction of a structural element for description. In addition, a “plan view,” “in a plan view,” or the similar expressions used in the present application means that a plane formed by the X direction and the Y direction as a “plane,” and this “plane” is viewed from the Z direction.

### First Embodiment

### Structure of Semiconductor Device

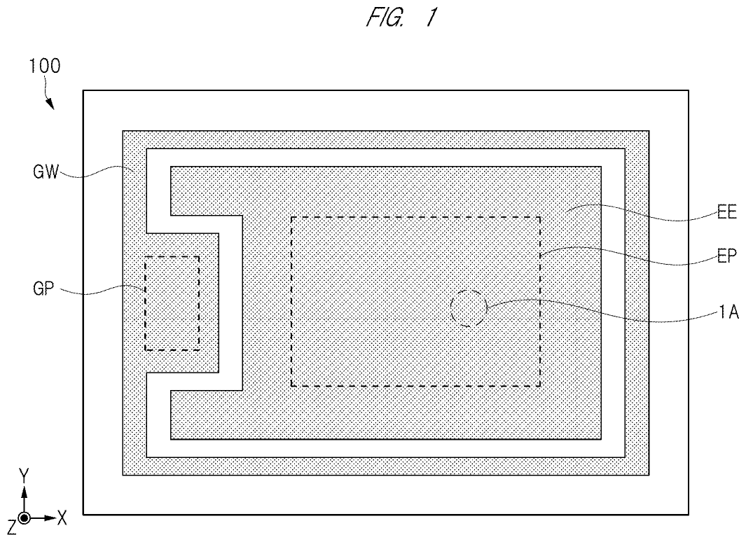

Hereinafter, with reference to FIG. 1 to FIG. 4, a structure of a semiconductor device 100 according to the first embodiment will be described. FIG. 1 is a plan view showing a semiconductor chip of the semiconductor device 100. As shown in FIG. 1, most part of the semiconductor device 100 is covered with an emitter electrode EE. A gate wiring GW is formed so as to surround the emitter electrode EE, in plan view.

Although not shown here, the emitter electrode EE and the gate wiring GW are covered with a protective film such as a polyimide film. Openings are provided in part of the protective film on the emitter electrode EE and on the gate wiring GW, regions exposed in the openings serve as an emitter pad EP and a gate pad GP. An external connection member such as a bonding wire or a clip (copper plate) is connected on the emitter pad EP and on the gate pad GP, so that the semiconductor device 100 is electrically connected to another semiconductor chip, a wiring substrate, or the like.

The semiconductor device 100 includes a cell region and a peripheral region surrounding the cell region. In the cell region, main semiconductor elements such as the IGBT are formed. In the peripheral region, the gate wiring GW and the like are formed. A region 1A shown in FIG. 1 indicates part of the cell region.

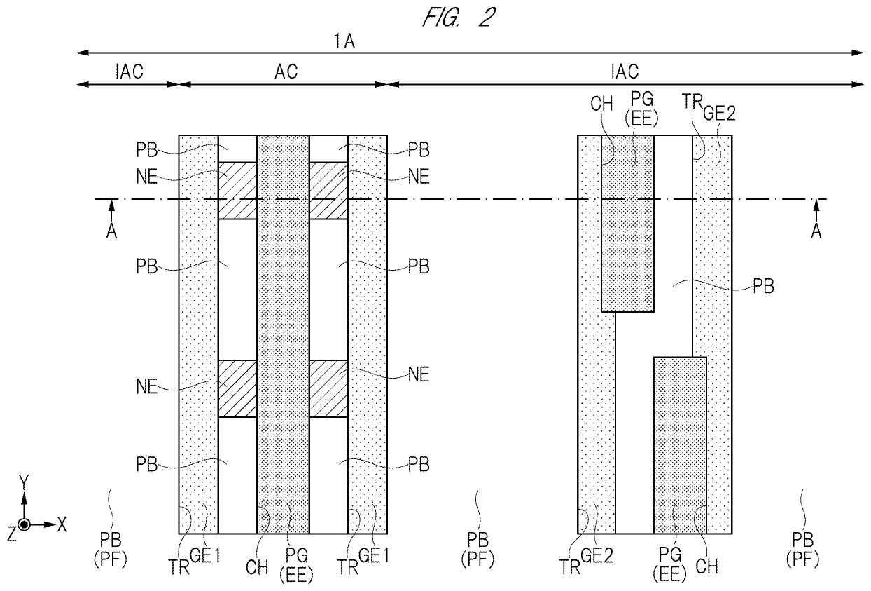

FIG. 2 is a plan view showing a main part corresponding to the region 1 shown in in FIG. 1. The IGBT shown in FIG. 2 is an IGBT of a GGEEs structure using the IE effect. The semiconductor device 100 has an active cell AC for carrying out main operation of the IGBT, and an inactive cell IAC other than the active cell AC.

As shown in FIG. 2, a plurality of trenches TR extend in the Y direction and are adjacent to each other in the X direction. In each of the trenches TR in the active cell AC, a gate electrode GE1 is formed. In each of the trenches TR in the inactive cell IAC, a gate electrode GE2 is formed. The trenches TR formed in the active cell AC and the gate electrodes GE1 formed therein constitute a gate trench. The trenches TR formed in the inactive cell IAC and the gate electrode GE2 formed therein constitute an emitter trench.

The gate electrode GE1 in the active cell AC has the gate wiring GW electrically connected thereto, to be supplied with a gate potential at a time of operation of the IGBT. The gate electrode GE2 in the inactive cell IAC has the emitter electrode EE electrically connected thereto, to be supplied with an emitter potential at a time of operation of the IGBT. In addition, a base region PB and an emitter region NE in the active cell AC and the base region PB in the inactive cell IAC have the emitter electrode EE electrically connected thereto, to be supplied with an emitter potential at a time of operation of the IGBT.

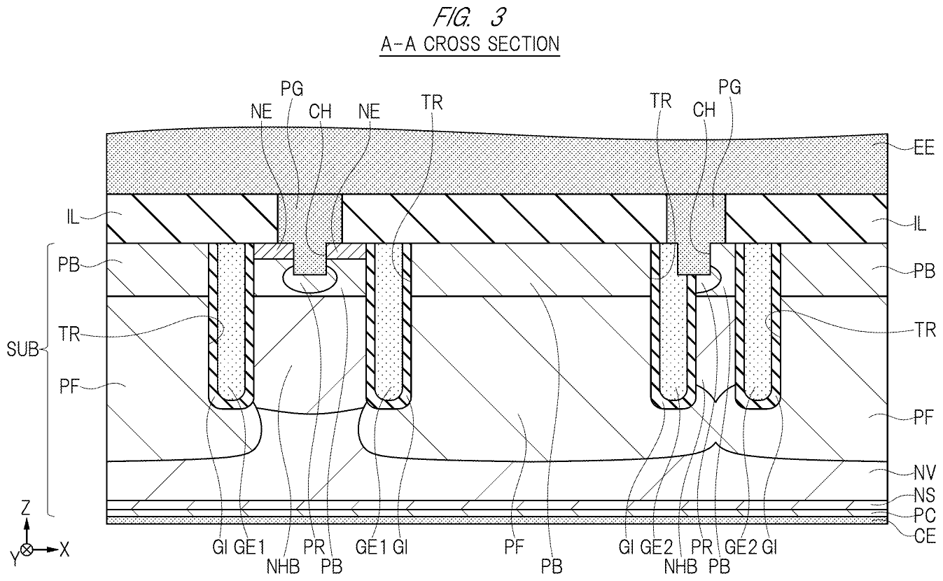

FIG. 3 is a cross-sectional view taken along a line A-A indicated in FIG. 2. The semiconductor device 100 includes an n-type semiconductor substrate SUB having an upper surface and a lower surface. The semiconductor substrate SUB has an n-type drift region NV. Here, the n-type semiconductor substrate SUB itself constitutes the drift region NV. Note that the semiconductor substrate SUB may be a laminated layer of an n-type silicon substrate and an n-type silicon layer obtained by doping with phosphorus (P) into the silicon substrate to grow through the epitaxial growth. In this case, the n-type silicon layer having an impurity concentration lower than that of the n-type silicon substrate constitutes the drift region NV.

On the lower surface side of the semiconductor substrate SUB, in the semiconductor substrate SUB, an n-type field stop region (impurity region) NS is formed. An impurity concentration of the field stop region NS is higher than that of the drift region NV. The field stop region NS is provided in order to prevent a depletion layer extending from a pn junction on the upper surface side of the semiconductor substrate SUB from reaching a p-type collector region PC, at a time of turning off the IGBT.

On the lower surface side of the semiconductor substrate SUB, in the semiconductor substrate SUB, the p-type collector region (impurity region) PC is formed. The collector region PC is positioned under the field stop region NS.

Under the lower surface of the semiconductor substrate SUB, a collector electrode CE is formed. The collector electrode CE is electrically connected to the collector region PC, supplying the collector region PC with a collector potential. The collector electrode CE is, for example, a single-layer metal film such as an Au film, an Ni film, a Ti film, or an AlSi film, or a multi-layer metal film obtained by having these films layered as appropriate.

On the upper surface side of the semiconductor substrate SUB, in the semiconductor substrate SUB, the trenches TR are formed. Each of the trenches T penetrates the emitter region NE and the base region PB which are described later, and reaches the semiconductor substrate SUB. A depth of the trench TR is, for example, 2 μm or more and 5 μm or less.

In the trench TR, a gate insulating film GI is formed. With the gate insulating film GI interposed between the gate electrode GE1 or GE2 and the trench TR, the gate electrode GE1 or GE2 is formed in the trench TR. The gate insulating film GI is an insulating film, and, for example, an oxide silicon film. The gate electrode GE1 or GE2 is a conductive film and, for example, a polysilicon film doped with n-type impurities. A thickness of the gate insulating film GI is, for example, 70 nm or more and 150 nm or less.

On the upper surface side of the semiconductor substrate SUB in the active cell AC, in the semiconductor substrate SUB between a pair of trenches TR (a pair of gate electrodes GE1), a hole barrier region (impurity region) NHB is formed. An impurity concentration of the hole barrier region NHB is higher than that of the drift region NV.

In the hole barrier region NHB, a p-type base region (impurity region) PB is formed. In the p-type base region PB, the n-type emitter region (impurity region) NE is formed. An impurity concentration of the emitter region NE is higher than that of the drift region NV. The base region PB is formed so as to be shallower than the depth of the trench TR, and the emitter region NE is formed so as to be shallower than a depth of the base region PB.

Note that, as shown in FIG. 2, a plurality of the emitter regions NE are formed between the pair of trenches TR (the pair of gate electrodes GE1) to be spaced apart from each other by a predetermined distance along the Y direction. The base region PB positioned below the emitter region NE adjacent to the gate electrode GE1 is used as a channel region.

On the upper surface side of the semiconductor substrate SUB in the inactive cell IAC, in the semiconductor substrate SUB between the pair of trenches TR (the pair of gate electrodes GE2), the hole barrier region NHB is formed. In addition, in the semiconductor substrate SUB between the gate electrode GE1 and the gate electrode GE2, a p-type floating region (impurity region) PF is formed. In the hole barrier region NHB and in the floating region PF, the p-type base region PB is formed. An impurity concentration of the base region PB is lower than that of the floating region PF.

The floating region PF and the base region PB formed in the floating region PF are not electrically connected to the gate wiring GW and the emitter electrode EE and are not supplied with a potential, thereby being in an electrically floating state.

In the active cell AC and the inactive cell IAC, an interlayer insulating film IL is formed over the upper surface of the semiconductor substrate SUB so as to cover each of the trenches TR. The interlayer insulating film IL is, for example, an oxide silicon film. A thickness of the interlayer insulating film IL is, for example, 600 nm or more and 1500 nm or less.

In the active cell AC, a hole CH penetrates the interlayer insulating film IL and the emitter region NE, and reaches the interior of the base region PB. The hole C is formed so as to be in contact with the emitter region NE and the base region PB.

On an upper side of the hole CH, the interlayer insulating film IL is recessed. Specifically, a size of an opening of the hole CH positioned higher than the upper surface of the semiconductor substrate SUB is larger than a size of an opening of the hole CH positioned lower than the upper surface of the semiconductor substrate SUB. Accordingly, part of an upper surface of the emitter region NE is exposed from the interlayer insulating film IL. Hence, the emitter electrode EE is in contact with not only a side surface of the emitter region NE, but also the part of the upper surface of the emitter region NE, in the contact hole CH. This makes it possible to reduce a contact resistance between the emitter electrode EE and the emitter region NE.

In the inactive cell IAC, the hole CH penetrates the interlayer insulating film IL and reaches the interior of the base region PB. In addition, the hole CH is formed so as to overlap with the gate electrode GE2, in plan view. Owing to this, the hole CH in the inactive cell IAC is formed so as to be in contact with the gate electrode GE2 and the base region PB.

In each of the active cell AC and the inactive cell IAC, in the base region PB around a bottom portion of the hole CH, a p-type high concentration diffusion region (impurity region) PR is formed. An impurity concentration of the high concentration diffusion region PR is higher than that of the base region PB. The high concentration diffusion region PR is provided so as to reduce a contact resistance to the emitter electrode EE and prevent latch-up.

A plug PG is buried in the hole CH. The plug PG includes a barrier metal film and a conductive film formed on the barrier metal film. The barrier metal film is, for example, a layered film including a titanium film and a titanium nitride film formed on the titanium film. The conductive film is formed of, for example, a tungsten film.

Note that, although no illustration is provided here, the hole CH is formed also on part of each of the gate electrodes GE1, and the plug PG is buried in this hole CH as well.

The emitter electrode EE is formed on the interlayer insulating film IL. The emitter electrode EE is electrically connected to the emitter region NE, the base region PB, the high concentration diffusion region PR, and the gate electrode GE2 through the hole CH (plug PG), supplying these regions with an emitter potential. Note that, although no illustration is provided here, the gate wiring GW formed in the same process as that of the emitter electrode EE is also formed on the interlayer insulating film IL. The gate wiring GW is electrically connected to the gate electrode GE1 through the hole CH (plug PG), supplying the gate electrode GE1 with a gate potential.

Such emitter electrode EE and gate wiring GW include, for example, a barrier metal film and a conductive film formed on the barrier metal film. The barrier metal film is, for example, a TiW film. The conductive film is, for example, an aluminum alloy film added with copper or silicon. The aluminum alloy film is a main conductive film of the emitter electrode EE and the gate wiring GW, and is sufficiently thicker than the TiW film.

### Main Features of First Embodiment

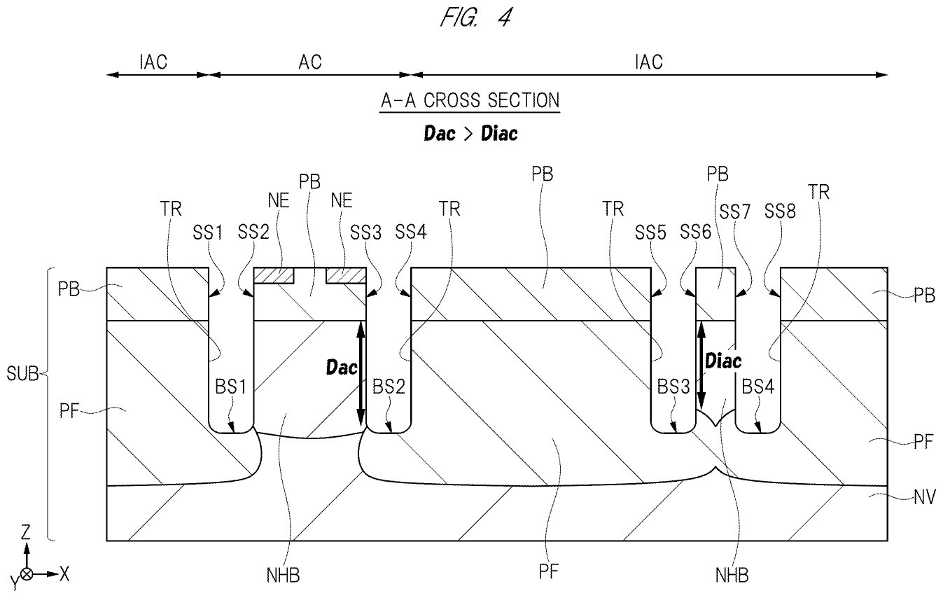

FIG. 4 is a cross-sectional view of a main part showing details of the trench TR and its periphery, of the cross-sectional structure in FIG. 3.

As shown in FIG. 4, one of the pair of trenches TR formed in the active cell AC has a side surface SS1, a side surface SS2 that is opposed to the side surface SS1, and a bottom surface BS1 connecting the side surface SS1 to the side surface SS2. The other of the pair of trenches TR in the active cell AC has a side surface SS3, a side surface SS4 that is opposed to the side surface SS3, and a bottom surface BS2 connecting the side surface SS3 to the side surface SS4. The one trench TR and the other trench TR are provided being spaced apart from each other such that the side surface SS2 and the side surface SS3 are adjacent to each other.

In addition, one of the pair of trenches TR formed in the inactive cell IAC has a side surface SS5, a side surface SS6 that is opposed to the side surface SS5, and a bottom surface BS3 connecting the side surface SS5 to the side surface SS6. The other of the pair of trenches TR in the inactive cell IAC has a side surface SS7, a side surface SS8 that is opposed to the side surface SS7, and a bottom surface BS4 connecting the side surface SS7 to the side surface SS8. The one trench TR and the other trench TR are provided being spaced apart from each other such that the side surface SS6 and the side surface SS7 are adjacent to each other.

Note that an interval between the pair of trenches TR in the inactive cell IAC is smaller than that between the pair of trenches TR in the active cell AC. In other words, a distance between the side surface SS6 and the side surface SS7 is smaller than that between the side surface SS2 and the side surface SS3.

Each of the floating region PF covers each of the bottom surfaces BS1 and BS of the trenches TR in the active cell AC, and covers each of the bottom surface BS3 and BS4 of the trenches TR in the inactive cell IAC. In addition, each of the floating regions PF is diffused also in a lateral direction (X direction) so as to reach the semiconductor substrate SUB between the trenches TR in the active cell AC, and reach the semiconductor substrate SUB between the trenches TR in the inactive cell IAC. The floating region PF covers not only the bottom surface of the trench TR, but also further extends in the lateral direction (X direction), so that a concentration of an electric field directly below the trench TR can be mitigated, allowing junction breakdown voltage to be improved.

In other words, the floating region PF formed in the semiconductor substrate SUB on the side surface SS1 side covers the bottom surface BS1 so as to extend beyond the side surface SS2. The floating region PF formed in the semiconductor substrate SUB between the side surface SS4 and the side surface SS5 covers the bottom surface BS2 so as to extend beyond the side surface SS3. These floating regions PF (the floating regions PF covering the bottom surfaces of the pair of trenches TR in the active cell AC) are not in contact with each other and are spaced apart from each other.

In addition, the floating region PF formed in the semiconductor substrate SUB between the side surface SS4 and the side surface SS5 covers the bottom surface BS3 in order to extend beyond the side surface SS6. The floating region PF formed in the semiconductor substrate SUB on the side surface SS8 side covers the bottom surface BS4 so as to extend beyond the side surface SS7. These floating regions PF (the floating regions PF covering the bottom surfaces of the pair of trenches TR in the inactive cell IAC) are in contact with each other.

Note that the hole barrier region NHB in the active cell AC is formed in the semiconductor substrate SUB between the side surface SS2 and the side surface SS3, the hole barrier region NHB in the inactive cell IAC is formed in the semiconductor substrate SUB between the side surface SS6 and the side surface SS7.

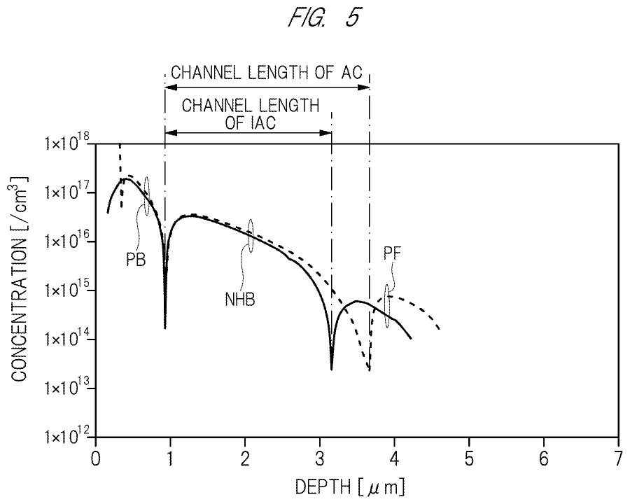

FIG. 5 shows a profile (broken line) of an impurity concentration of the semiconductor substrate SUB in the active cell AC between the pair of trenches TR and a profile (solid line) of an impurity concentration of the semiconductor substrate SUB in the inactive cell IAC between the pair of trenches TR. Note that the profile (broken line) of the impurity concentration of the semiconductor substrate SUB in the active cell AC is obtained at a position close to the side surface SS2 or the side surface SS3, and the profile (solid line) of the impurity concentration of the semiconductor substrate SUB in the inactive cell IAC is obtained at a position close to the side surface SS6 or the side surface SS7.

Here, focusing on a parasitic PMOS transistor of each of the active cell AC and the inactive cell IAC, a channel length of the parasitic PMOS transistor in the inactive cell IAC is shorter than a channel length of the parasitic PMOS transistor in the active cell AC.

Specifically, as shown in FIG. 4 and FIG. 5, a distance Diac between the base region PB and the floating region PF in the inactive cell IAC is shorter than a distance Dac between the base region PB and the floating region PF in the active cell AC. Note that the distance Diac is a distance along the side surface SS6 or the side surface SS7, and the distance Dac is a distance along the side surface SS2 or the side surface SS3. In other words, a depth of the hole barrier region NHB along the side surface SS6 or the side surface SS7 is greater than a depth of the hole barrier region NHB along the side surface SS2 of the side surface SS3.

In addition, as shown in FIG. 5, of the hole barrier region NHB in the inactive cell IAC, the impurity concentration of the hole barrier region NHB at a portion in the vicinity of a boundary between the floating region PF and the hole barrier region NHB is lower than the impurity concentration of the hole barrier region NHB in the active cell AC at a depth same as the portion described above. Specifically, part of a channel region of the parasitic PMOS transistor in the inactive cell IAC is likely to be turned on.

The parasitic PMOS transistor in the inactive cell IAC is configured in the manner described above, allowing the parasitic PMOS transistor in the inactive cell IAC to operate at a higher speed than the parasitic PMOS transistor in the active cell AC.

Accordingly, in a transient state at a time of switching operation of the IGBT, when the parasitic PMOS transistor is turned on, a hole current flowing through the parasitic PMOS transistor in the inactive cell IAC increases, and a hole current flowing through the parasitic PMOS transistor in the active cell AC decreases.

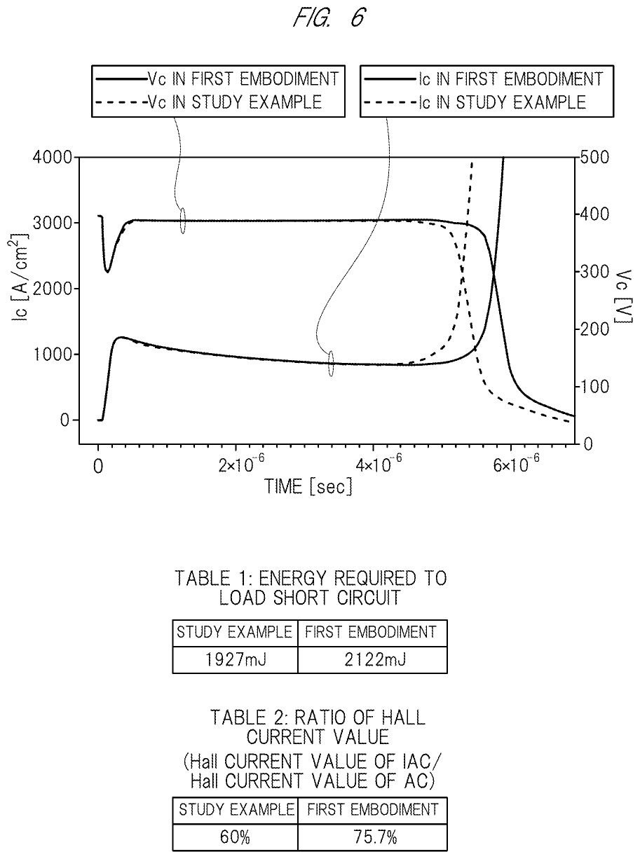

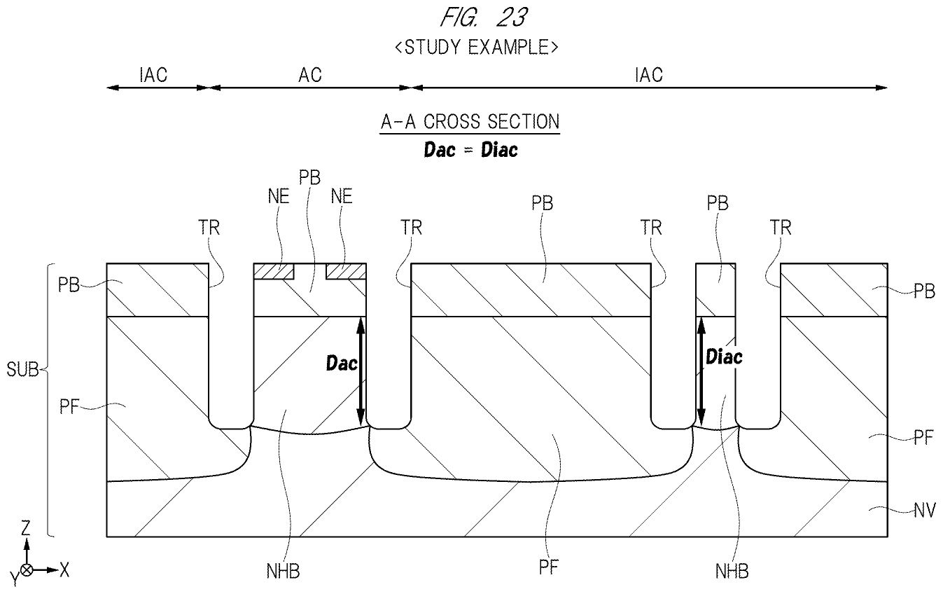

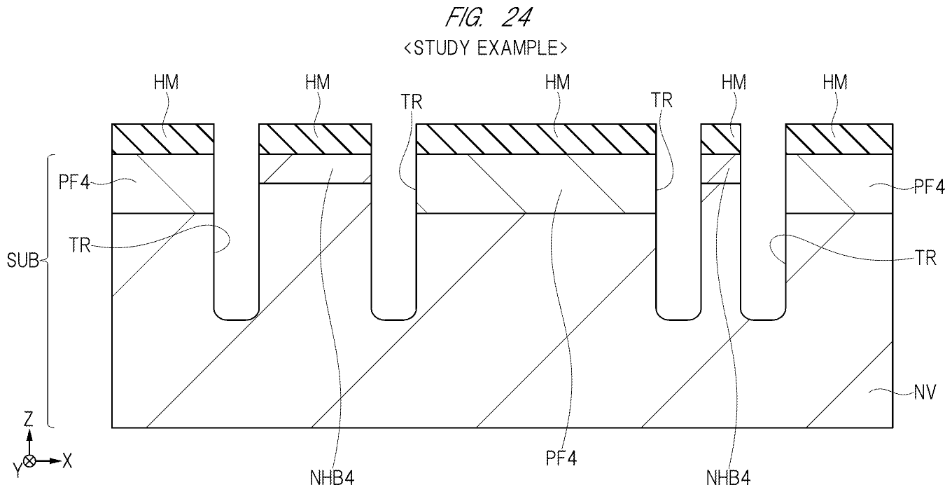

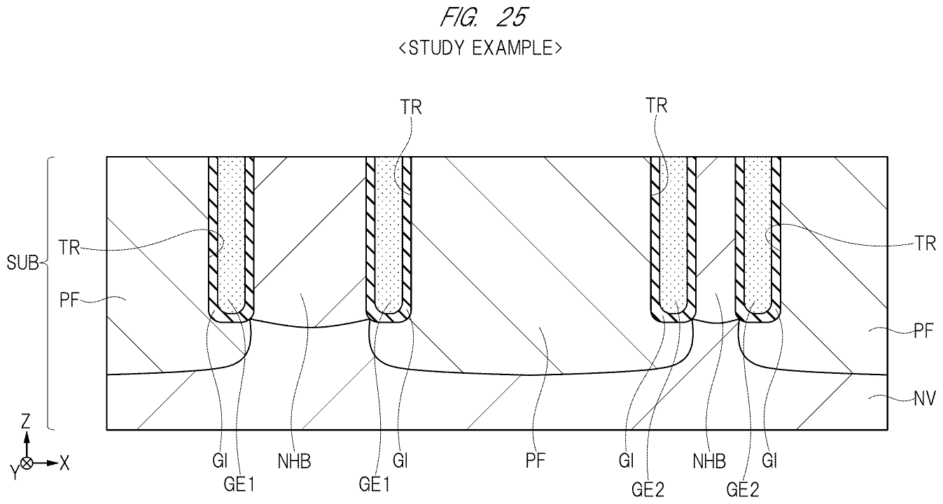

In the following, with reference to FIG. 6, FIG. 23, FIG. 24, and FIG. 25, a comparison between the IGBT in the first embodiment and an IGBT in a study example is carried out. FIG. 23 shows the IGBT in the study example conducted by the inventors of the present application on the basis of Patent Document 1 and the like. Note that FIG. 23 shows trenches TR and part of the configuration around the trenches TR, as in FIG. 4 of the first embodiment.

Although a description will be given in detail later, in the first embodiment, by high-energy ion implantation, ion implantation layers NHB1 to NHB3 and ion implantation layers PF1 and PF2 are formed at a region closer to a region in which the floating region PF and the hole barrier region NHB are to be formed. For example, a position of a peak of an impurity concentration of the ion implantation layer PF1 is substantially the same as positions of the bottom surface BS1 to BS4 of the respective trenches TR, or deeper than the positions of the bottom surface BS1 to BS4 of the respective trenches TR. Then, after the trenches TR are formed, a heat treatment at a relatively low temperature like 1100° C. is applied to the semiconductor substrate SUB, and accordingly, the floating region PF and the hole barrier region NHB are formed.

Meanwhile, in the study example, as shown in FIG. 24 and FIG. 25, after low-energy ion implantation is applied to the semiconductor substrate SUB to form an ion implantation layer PF4 and an ion implantation layer NHB4, the trenches TR are formed. After that, a heat treatment at a high temperature and for a long period of time is carried out for example, under a condition at 1200° C. for 30 minutes, impurities contained in the ion implantation layer PF4 and the ion implantation layer NHB4 are diffused, thereby forming the floating region PF and the hole barrier region NHB.

In the study example, at a time at which the impurities are diffused, diffusion of the impurities in a lateral direction is likely to be disturbed by the trenches TR. Hence, an amount of diffusion of the floating region PF to a region between the pair of trenches TR becomes substantially the same between the inactive cell IAC and the active cell AC. Note that, when the heat treatment is reinforced to make the amount of diffusion greater, two floating regions PF covering the bottom surfaces of the pair of trenches TR in the inactive cell IAC can also be brought into contact with each other.

Specifically, as shown in FIG. 23, in the study example, the distance Diac is substantially the same as the distance Dac. In other words, the channel length of the parasitic PMOS transistor in the inactive cell IAC are substantially the same as the channel length of the parasitic PMOS transistor in the active cell AC.

FIG. 6 indicates a result of experiment on a short circuit withstand test using a typical short circuit. Note that, in this test, a power supply voltage is set to 400 V, and evaluates a short circuit withstand time by applying a voltage of 0 to 15 V to the gate electrode GE1. As indicated in a graph of FIG. 6, it becomes clear that short circuit withstand times in both a collector current Ic and a collector voltage Vc in the first embodiment are improved more than those in the study example.

In addition, a table 1 of FIG. 6 indicates a result obtained by calculating an energy required to a load short circuit. A table 2 of FIG. 6 indicates a result by calculating a ratio of a Hall current value of the inactive cell IAC relative to a Hall current value of the active cell AC in each of the first embodiment and the study example. It becomes clear that an energy required to a load short circuit in the first embodiment is greater than that in the study example and the short circuit withstand time in the first embodiment is improved more than that in the study example. In addition, the Hall current value of the inactive cell IAC in the first embodiment is greater than that in the study example. Hence, latch-up breakdown in the active cell AC is less likely to occur, and a concentration of heat load on the active cell AC is mitigated, so that the RBSOA can be improved.

As described above, according to the first embodiment, robustness in the load short circuit, the RBSOA, and the like can be improved, so that the performance of the semiconductor device 100 having the IGBT can be enhanced.

### Manufacturing Method of Semiconductor Device

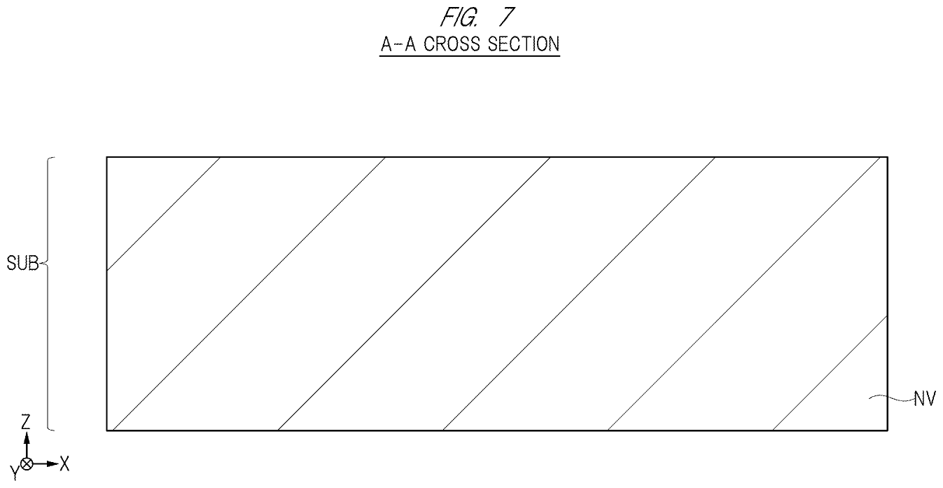

In the following, with reference to FIG. 7 to FIG. 16, each process included in a manufacturing method of the semiconductor device 100 according to the first embodiment will be described.

As shown in FIG. 7, first, an n-type semiconductor substrate SUB having an upper surface and a lower surface is provided. As described above, although the n-type semiconductor substrate SUB itself constitutes the drift region NV here, the semiconductor substrate SUB may be a laminated layer of an n-type silicon substrate and an n-type silicon layer obtained by doping with phosphorus (P) into the silicon substrate to grow through the epitaxial growth.

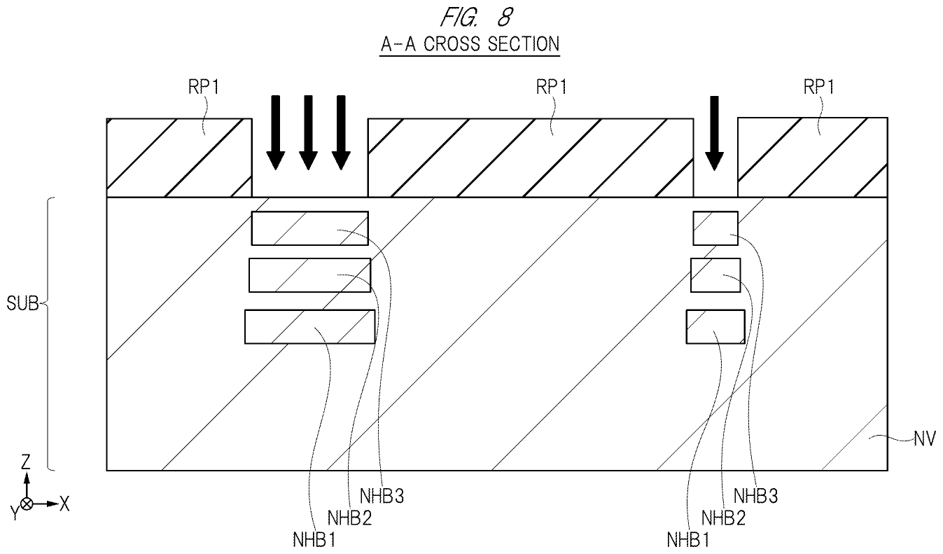

As shown in FIG. 8, in the semiconductor substrate SUB, the ion implantation layers NHB1 to NHB3 are formed. First, on the upper surface of the semiconductor substrate SUB, a resist pattern RP1 is formed. The resist pattern RP1 has a pattern for opening a region that is to serve as the hole barrier region NHB of each of the active cell AC and the inactive cell IAC in a later step. Next, with the resist pattern RP1 as a mask, n-type ion implantation is carried out to the semiconductor substrate SUB from the upper surface side of the semiconductor substrate SUB multiple times. Here, a case in which the third round of n-type ion implantation is to be carried out will be given as an example. Note that, after the third round of n-type ion implantation, an ashing treatment is carried out to remove the resist pattern RP1.

The first round of n-type ion implantation is carried out under a condition in which phosphorus (P) is implanted as an ion species at an energy of 1000 keV and in a dose amount of 3.0×10¹²/cm². As a result, the ion implantation layer NHB1 is formed in the semiconductor substrate SUB.

The second round of n-type ion implantation is carried out under a condition in which phosphorus (P) is implanted as an ion species at an energy of 600 keV and in a dose amount of 3.0×10¹²/cm². As a result, the ion implantation layer NHB2 is formed in the semiconductor substrate SUB. The ion implantation layer NHB2 is formed in the semiconductor substrate SUB at a region overlapping with the ion implantation layer NHB1, in plan view, and is positioned higher than the ion implantation layer NHB1.

The third round of n-type ion implantation is carried out under a condition in which phosphorus (P) is implanted as an ion species at an energy of 300 keV and in a dose amount of 4.0×10¹²/cm². As a result, the ion implantation layer NHB3 is formed in the semiconductor substrate SUB. The ion implantation layer NHB3 is formed in the semiconductor substrate SUB at a region overlapping with the ion implantation layer NHB2, in plan view, and is positioned higher than the ion implantation layer NHB2.

In this case, the greater the energy is, the deeper the ion implantation layer is formed. However, when the ion implantation is carried out, crystal defects are generated in the semiconductor substrate SUB. When the ion implantation layers are formed in order from a shallow position, at a time of carrying out the ion implantation at a deep position, a profile of the impurity concentration may be disturbed due to the crystal defects generated at the shallow position. Hence, it is preferred that the ion implantation at a deeper position may be carried out first.

Specifically, although energies in the first to third rounds of n-type ion implantation are different from each other, the n-type ion implantation having a greater energy is preferably carried out first. Hence, it is preferred that the first round of n-type ion implantation is carried out first, the second round of n-type ion implantation is carried out second, and then, the third round of n-type ion implantation is carried out last.

In addition, when the dose amount of ion implantation is greater, a probability of generation of crystal defects becomes higher. Accordingly, it is preferred that the dose amount of the ion implantation which is to be carried out first is small and the dose amount of the ion implantation which is to be carried out later is greater. Hence, disturbance of the profile of the impurity concentration due to the crystal defects can be suppressed as much as possible.

In addition, the first to third rounds of n-type ion implantation are carried out at an angle vertical to the upper surface of the semiconductor substrate SUB. In the ion implantation at a deep position, the ions collide with each other and are likely to be scattered. Owing to this, the ion implantation layer to be formed at a deeper position is likely to extend in a lateral direction. Hence, a width of the ion implantation layer NHB1 is larger than a width of the ion implantation layer NHB2, and the width of the ion implantation layer NHB2 is larger than a width of the ion implantation layer NHB3.

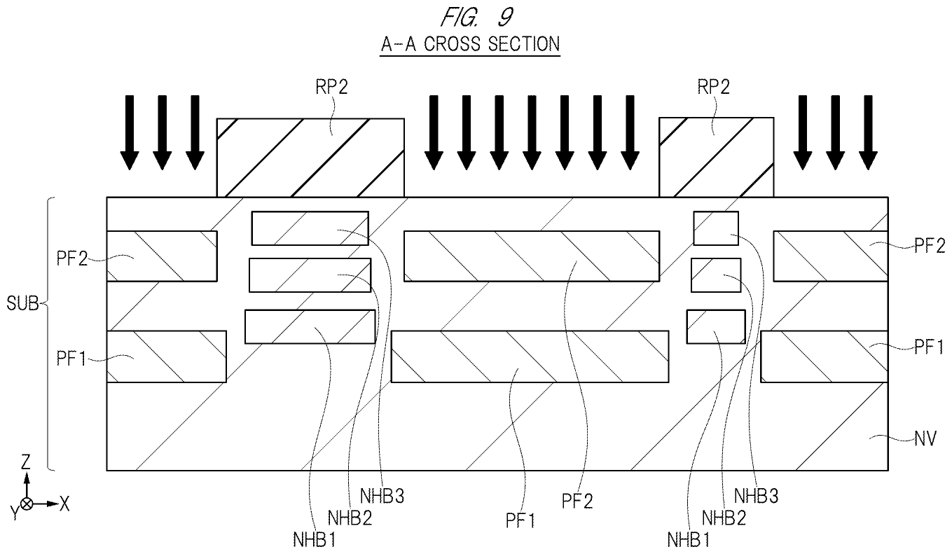

As shown in FIG. 9, the ion implantation layers PF1 and PF2 are formed in the semiconductor substrate SUB. First, a resist pattern RP2 is formed over the upper surface of the semiconductor substrate SUB. The resist pattern RP2 has a pattern for opening a region that is to serve as the floating region PF. Next, with the resist pattern RP2 as a mask, p-type ion implantation is carried out to the semiconductor substrate SUB from the upper surface side of the semiconductor substrate SUB multiple times. Here, a case in which the second round of p-type ion implantation will be given as an example. Note that, after the second round of p-type ion implantation, the ashing treatment is carried out to remove the resist pattern RP2.

The first round of p-type ion implantation is carried out under a condition in which boron (B) is implanted as an ion species at an energy of 1250 keV and in a dose amount of 1.25×10¹³/cm². Hence, the ion implantation layer PF1 is formed in the semiconductor substrate SUB.

The second round of p-type ion implantation is carried out under a condition in which boron (B) is implanted as an ion species at an energy of 300 keV and in a dose amount of 2.75×10¹³/cm². Hence, the ion implantation layer PF2 is formed in the semiconductor substrate SUB. The ion implantation layer PF2 is formed in the semiconductor substrate SUB at a position overlapping with the ion implantation layer PF1, in plan view, and is positioned higher than the ion implantation layer PF1.

Also in this case, the energies for the first and second rounds of p-type ion implantation are different from each other. However, for the same reasons in the first to third rounds of n-type ion implantation, it is preferred that the p-type ion implantation having a greater energy and a low concentration is carried out first. Accordingly, it is preferred that the first round of p-type ion implantation is first carried out, and then, the second round of p-type ion implantation is carried out. In addition, the first and second rounds of p-type ion implantation are also carried out at an angle vertical to the upper surface of the semiconductor substrate SUB. For the same reason as the relation to each width of the ion implantation layers NHB1 to NHB3, a width of the ion implantation layer PF1 is larger than a width of the ion implantation layer PF2.

Note that a manufacturing process of forming the ion implantation layers PF1 and PF2 may be carried out before a manufacturing process of forming the ion implantation layers NHB1 to NHB3.

Next, after the ion implantation layers NHB1 to NHB3 and the ion implantation layers PF1 and PF2 are formed, a heat treatment is carried out to the semiconductor substrate SUB. This heat treatment is carried out in the atmosphere filled with inactive gas such as nitrogen gas, for example, under a condition at 700° C. or more and 950° C. or less and for 30 seconds or more and 150 seconds or less. More preferably, this heat treatment is carried out under a condition at 950° C. or less and for 30 seconds.

This heat treatment activates the impurities (B) contained in each of the ion implantation layers PF1 and PF2, while activating the impurities (P) contained in each of the ion implantation layers NHB1 to NHB3. In addition, this heat treatment causes the crystal defects generated at a time of ion implantation to become normal.

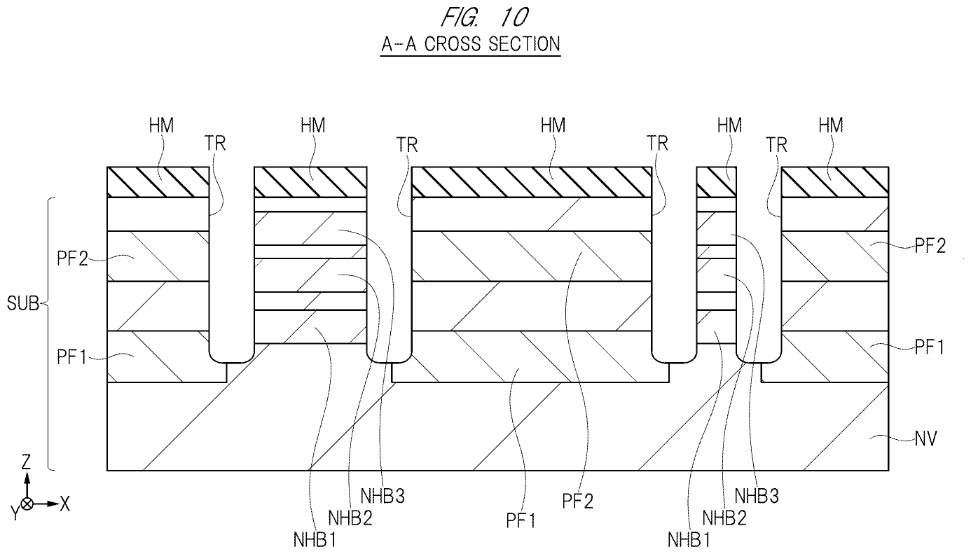

As shown in FIG. 10, on the upper surface side of the semiconductor substrate SUB, the trenches TR are formed in the semiconductor substrate SUB. First, an oxide silicon film, for example, is formed over the upper surface of the semiconductor substrate SUB through the CVD, for example. Next, a resist pattern having openings is formed over the oxide silicon film. Next, with the resist pattern as a mask, anisotropic etching is carried out to perform patterning on the oxide silicon film, thereby forming a hard mask HM. Next, the ashing treatment is carried out to remove the resist pattern.

Next, with the hard mask HM as a mask, anisotropic etching is carried out to form the trenches TR in the semiconductor substrate SUB. Then, for example, by wet etching with a solution containing hydrofluoric acid, the hard mask HM is removed.

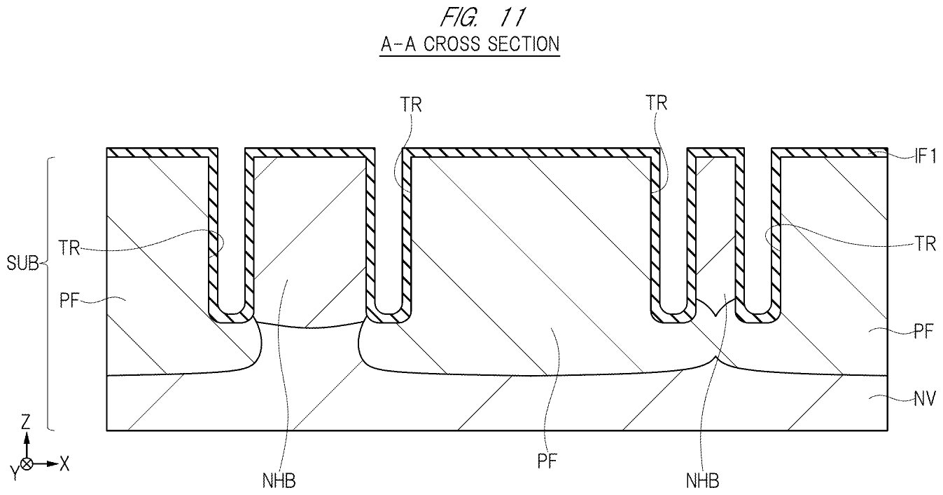

As shown in FIG. 11, inside the trenches TR and over the upper surface of the semiconductor substrate SUB, a sacrificial oxide film IF1 is formed. Accordingly, a damaged layer formed in the semiconductor substrate SUB is removed. Subsequently, for example, by isotropic etching with a solution containing hydrofluoric acid, the sacrificial oxide film is removed.

Note that the sacrificial oxide film IF1 is formed on the semiconductor substrate SUB by carrying out the heat treatment. This heat treatment is carried out under a condition at a higher temperature and for a longer period of time than the heat treatment for activating the impurities as shown in FIG. 9. For example, this heat treatment is carried out in the atmosphere filled with oxygen gas, under a condition at 1100° C. and for 30 minutes or more and 60 minutes or less. Accordingly, the impurities (B) contained in each of the ion implantation layers PF1 and PF2 and the impurities (P) contained in each of the ion implantation layers NHB1 to NHB3 are diffused, so that the p-type floating region PF and the n-type hole barrier region NHB are formed.

In the first embodiment, at a time point before the heat treatment in FIG. 11, multiple rounds of ion implantation have been carried out, whereby the ion implantation layers NHB1 to NHB3 and the ion implantation layers PF1 and PF2 are formed closer to a region in which the floating region PF and the hole barrier region NHB are to be formed. Particularly, the ion implantation layer NHB1 and the ion implantation layer PF1 are formed at a deep position in advance. The trenches TR are formed such that the bottom surfaces BS1 to BS4 of the trenches TR are positioned lower than the ion implantation layer PF1. For example, the position of the peak of the impurity concentration of the ion implantation layer PF1 is substantially same as the positions of the bottom surfaces BS1 to BS4 of the trenches TR or deeper than the positions of the bottom surfaces BS1 to BS4 of the trenches TR. In the study example, the heat treatment is carried out under a condition at a higher temperature and for a longer period of time (1200° C., 30 minutes). However, in the first embodiment, the heat treatment can be carried out under a condition at a low temperature.

In addition, as in the study example, at the time of the heat treatment in FIG. 11, diffusion of the impurities is not hindered by the trenches TR, and accordingly, a bottom portion of each of the trenches TR is easily covered with each of the floating regions PF. In addition, between the pair of trenches TR in the inactive cell IAC, two adjacent ones of the floating regions PF are likely to be in contact with each other.

At this point, a positional relation of each of the floating regions PF and each of the trenches TR is as shown in FIG. 4. Specifically, each of the bottom surfaces BS1 to BS4 is covered with each of the floating regions PF. In addition, between the pair of trenches TR in the inactive cell IAC, two adjacent ones of the floating regions PF are in contact with each other. In addition, the position of the floating region PF between the pair of trenches TR in the inactive cell IAC from the upper surface of the semiconductor substrate SUB is shallower than the position of the floating region PF between the pair of trenches TR in the active cell AC from the upper surface of the semiconductor substrate SUB.

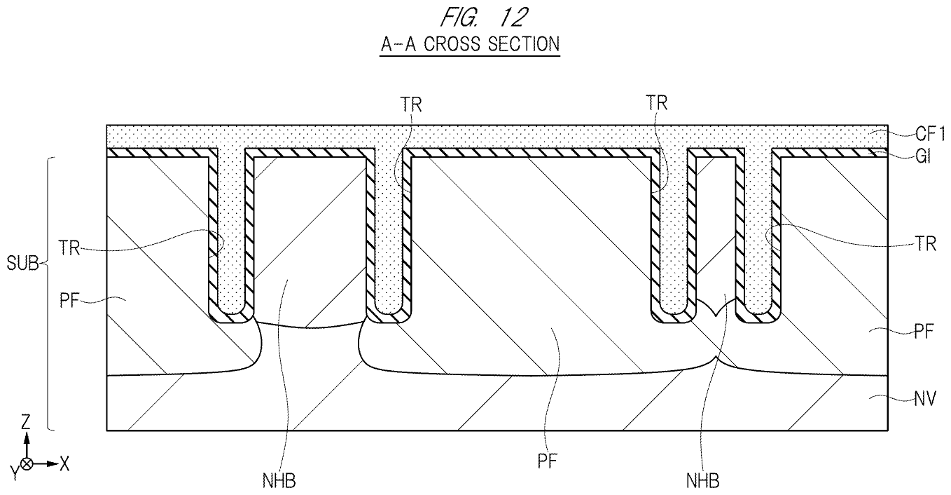

As shown in FIG. 12, in the trench TR, the gate insulating film GI and the conductive film CF1 are formed. First, the gate insulating film GI is formed in the trenches TR and over the upper surface of the semiconductor substrate SUB, by thermal oxidation. The gate insulating film GI is an oxide silicon film formed by the heat treatment with oxygen gas and hydrogen gas, under a condition at 950° C. and for 60 minutes, for example.

Next, the conductive film CF1 is formed so as to bury the interior of each of the trenches TR with the gate insulating film GI interposed between the trenches TR and the conductive film CF1, in the trenches TR and over the upper surface of the semiconductor substrate SUB, by the CVD, for example. The conductive film CF1 is a polycrystalline silicon film doped with, for example, n-type impurities.

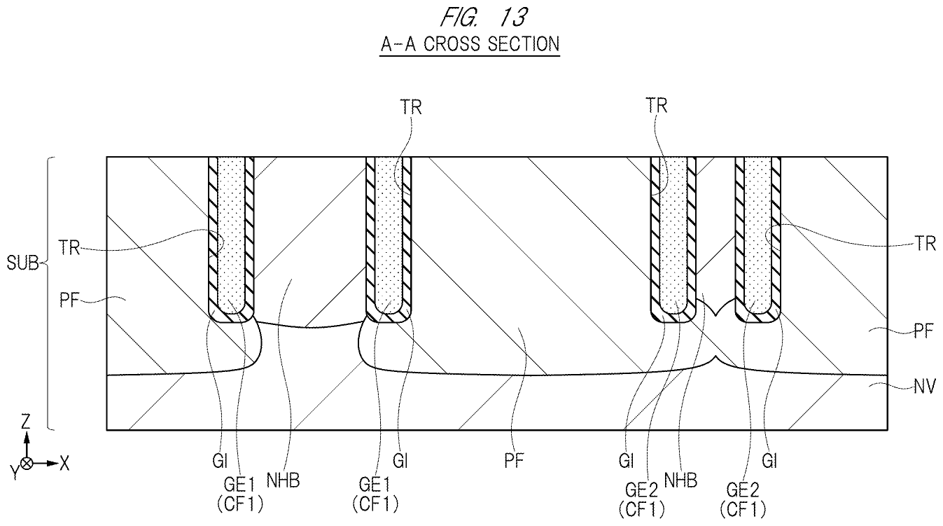

As shown in FIG. 13, the gate insulating film GI and the gate electrode GE1 or GE2 are formed in each of the trenches TR. First, by anisotropic etching, the conductive film CF1 formed outside the trenches TR is removed. The conductive film CF1 formed in each of the trenches TR remains as the gate electrode GE1 or GE2. Next, by isotropic etching or anisotropic etching, or etching performed in combination of these etching techniques, the gate insulating film GI formed outside each of the trenches TR is removed.

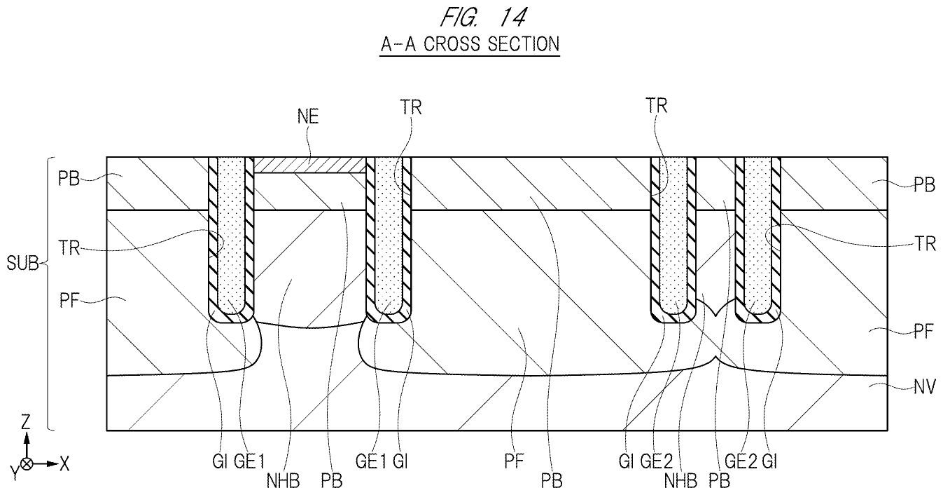

As shown in FIG. 14, by photolithography and ion implantation, on the upper surface side of the semiconductor substrate SUB, the p-type base region PB is formed in the semiconductor substrate SUB (floating region PF and hole barrier region NHB). Next, by photolithography and ion implantation, in the base region PB of the active cell AC, an n-type emitter region NE is selectively formed. Subsequently, the heat treatment for activating the impurities contained in the base region PB and the emitter region NE is carried out.

Note that, at this point, each of the floating regions PF and each of the base regions PB are formed so as to have a relation between the distance Diac and the distance Dac indicated in FIG. 4. In addition, the profile of the impurity concentration shown in FIG. 5 is configured.

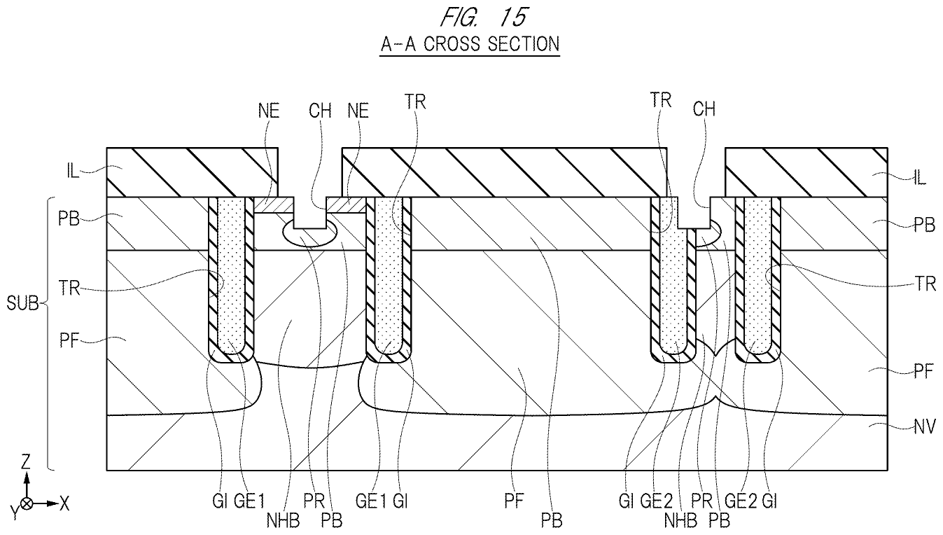

As shown in FIG. 15, first, in the active cell AC and the inactive cell IAC, the interlayer insulating film IL is formed over the upper surface of the semiconductor substrate SUB so as to cover the trenches TR, by the CVD, for example. The interlayer insulating film IL is an oxide silicon film, for example.

Next, by photolithography and anisotropic etching, in the active cell AC, the hole CH is formed in the interlayer insulating film IL, the emitter region NE, and the base region PB. A bottom portion of the hole CH is positioned in the base region PB.

Here, the hole CH is formed in the inactive cell IAC as well, and this hole CH is formed so as to overlap with the gate electrode GE2, in plan view. Owing to this, the hole CH in the inactive cell IAC is formed so as to be in contact with the gate electrode GE2 and the base region PB. Note that, although not illustrated, the hole CH is formed also above some of the gate electrodes GE1.

Next, by photolithography and ion implantation, at the bottom portion of the hole CH, the p-type high concentration diffusion region PR is selectively formed in the base region PB. Next, the interlayer insulating film IL is subjected to isotropic etching, so that the interlayer insulating film IL is recessed. Accordingly, an opening width of the hole CH which is positioned on the upper surface of the semiconductor substrate SUB becomes larger than an opening width of the hole CH which is positioned in the semiconductor substrate SUB.

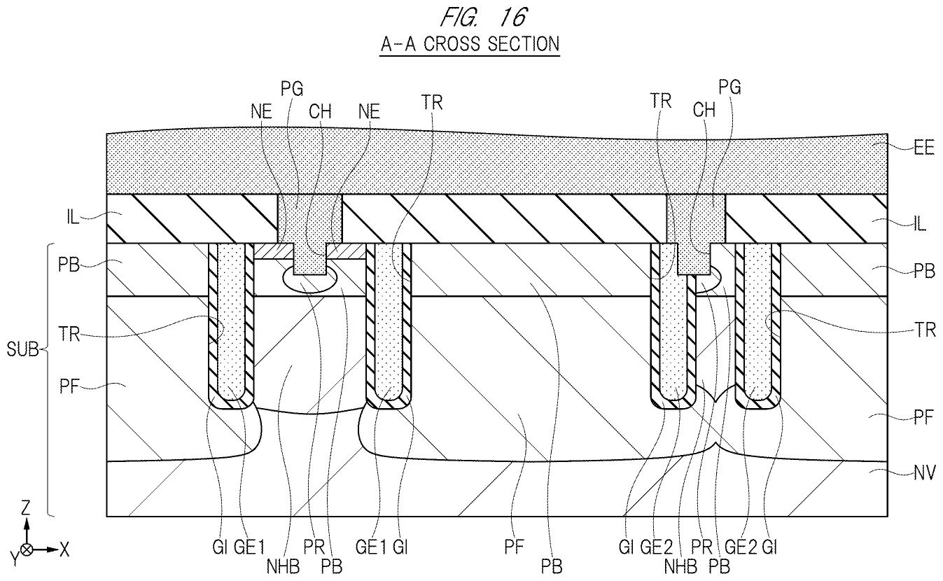

As shown in FIG. 16, the plug PG is formed in the hole CH. First, in the hole CH and over the interlayer insulating film IL, a barrier metal film is formed. For example, a titanium film is formed in the hole CH and over the interlayer insulating film IL by sputtering, and for example, a titanium nitride film is formed over the titanium film by sputtering, so that the barrier metal film can be formed. Next, in such a manner as to bury the interior of the hole CH, for example, a conductive film including a tungsten film is formed over the barrier metal film, for example, by the CVD. Next, by anisotropic etching, the conductive film and the barrier metal film which are formed outside the hole CH are removed. As a result, in such a manner as to bury the interior of the hole CH, the plug PG is formed.

Next, the emitter electrode EE is formed on the interlayer insulating film IL. First, for example, a TiW film is formed on the interlayer insulating film IL by sputtering, and for example, an aluminum alloy film is formed on the TiW film by sputtering. Next, by photolithography and dry etching, the TiW film and the aluminum alloy film are patterned to form the emitter electrode EE. Note that, although not illustrated here, the gate wiring GW is also formed on the interlayer insulating film IL through the same process as that of forming the emitter electrode EE.

After that, through the following manufacturing process, a structure shown in FIG. 3 is obtained. First, ion implantation is carried out from the lower surface side of the semiconductor substrate SUB, so that the n-type field stop region NS and the p-type collector region PC are formed. After the ion implantation is carried out for formation of these regions, laser annealing is carried out to these regions, activating impurities contained in the field stop region NS and the collector region PC. Next, below the lower surface of the semiconductor substrate SUB, for example, a metal film such as an Au film, an Ni film, and a Ti film or an AlSi film is formed by sputtering, for example. This metal film serves as the collector electrode CE. The collector electrode CE may be a layered film obtained by layering the above-described metal film on top of another, as needed.

### Second Embodiment

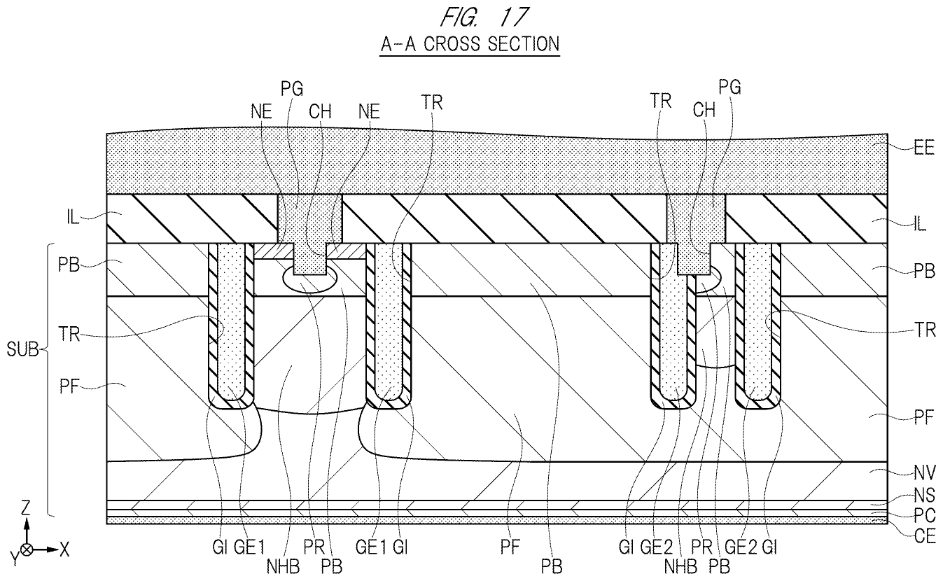

With reference to FIG. 17 to FIG. 21, a semiconductor device 100 according to the second embodiment and a method of manufacturing the same will be described below. Note that, in the following description, a difference from the first embodiment will mainly be described, and overlapping description with the first embodiment will be omitted.

In the second embodiment, a manufacturing process for the floating region PF is designed such that a channel length of the parasitic PMOS transistor of the inactive cell IAC becomes small more positively. Accordingly, in the second embodiment, as shown in FIG. 17, a position of the floating region PF between the pair of trenches TR of the inactive cell IAC from the upper surface of the semiconductor substrate SUB is shallower than that in the first embodiment. Hence, the distance Diac that has been described in FIG. 4 is shorter than that in the first embodiment.

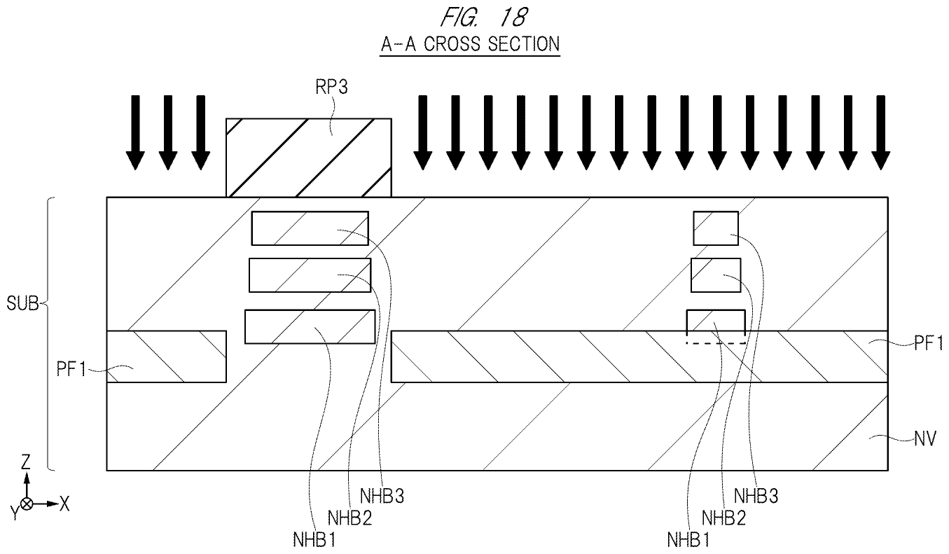

With reference to FIG. 18 to FIG. 20, the manufacturing process for such floating region PF will be described below. The manufacturing process shown in FIG. 18 to FIG. 20 is carried out in place of FIG. 8 to FIG. 10.

As shown in FIG. 18, in the semiconductor substrate SUB, a plurality of ion implantation layers PF1 are formed. First, over the upper surface of the semiconductor substrate SUB, the resist pattern RP3 is formed. The resist pattern RP3 has a pattern which covers the active cell AC and opens the inactive cell IAC.

Next, with the resist pattern RP3 as a mask, the first round of p-type ion implantation is carried out to the semiconductor substrate SUB from the upper surface side of the semiconductor substrate SUB. This first round of p-type ion implantation is the same as that described in FIG. 9. As a result, the plurality of ion implantation layers PF1 are formed in the semiconductor substrate SUB of the inactive cell IAC. In the second embodiment, unlike the first embodiment, the ion implantation layer PF1 is formed also at such a position as to overlap with a position at which the hole barrier region NHB (ion implantation layer NHB1 to NHB3) is to be formed, in plan view. Subsequently, the ashing treatment is carried out to remove the resist pattern RP3.

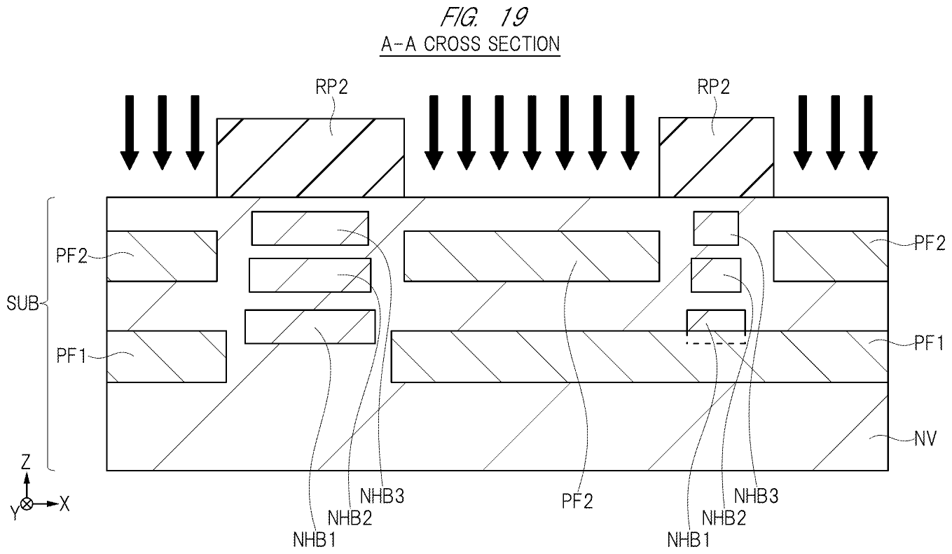

As shown in FIG. 19, the plurality of ion implantation layers PF2 are formed in the semiconductor substrate SUB. First, the resist pattern RP2 is formed over the upper surface of the semiconductor substrate SUB. Next, with the resist pattern RP2 as a mask, the second round of p-type ion implantation is carried out to the semiconductor substrate SUB from the upper surface side of the semiconductor substrate SUB. The resist pattern RP2 and the second round of p-type ion implantation are the same as those described in FIG. 9. Accordingly, in the semiconductor substrate SUB, the ion implantation layers PF2 are formed. The ion implantation layer PF2 is formed in the semiconductor substrate SUB at such a position as to overlap with the ion implantation layer PF1, in plan view and is positioned higher than the ion implantation layer PF1. Subsequently, the ashing treatment is carried out to remove the resist pattern RP2.

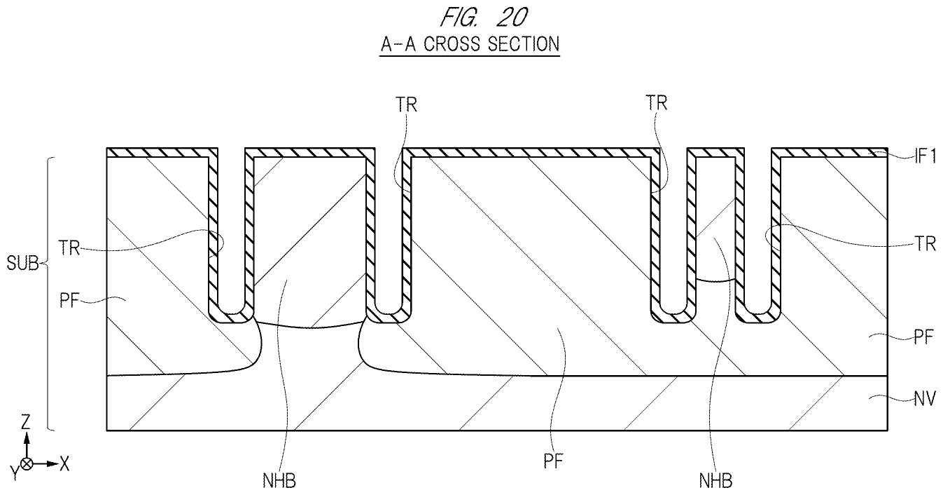

As shown in FIG. 20, after the ion implantation layers NHB1 to NHB3 and the ion implantation layers PF1 and PF2 are formed, the trenches TR are formed, and the sacrificial oxide film IF1 is then formed. A heat treatment for forming the sacrificial oxide film IF1 is similar to the heat treatment described in FIG. 10.

As a result of the heat treatment in FIG. 20, the impurities (B) contained in each of the ion implantation layers PF1 and PF2 are diffused to form the p-type floating region PF, and the impurities (P) contained in each of the ion implantation layers NHB1 to NHB3 are diffused to form the n-type hole barrier region NHB.

In this manner, the ion implantation layer PF1 is preliminarily formed also at a position corresponding to a portion between the pair of trenches TR of the inactive cell IAC, resulting in positive contact between the floating region PF on the side surface SS5 side and the floating region PF on the side surface SS8 side.

In addition, the ion implantation layer PF1 is formed at a depth overlapping with part of the ion implantation layer NHB1. Owing to this, the position of the floating region PF between the pair of trenches TR of the inactive cell IAC from the upper surface of the semiconductor substrate SUB is shallower than that in the first embodiment.

From a perspective of bringing the two floating regions PF into positive contact with each other, the second embodiment is more excellent than the first embodiment. However, in the second embodiment, the resist pattern RP3 is required. Hence, the first embodiment is more advantageous in that increase in manufacturing costs in the first embodiment can be more reduced than that in the second embodiment.

In addition, the technique described in the second embodiment is effective in the GGEEs structure and more effective in the GGEE structure.

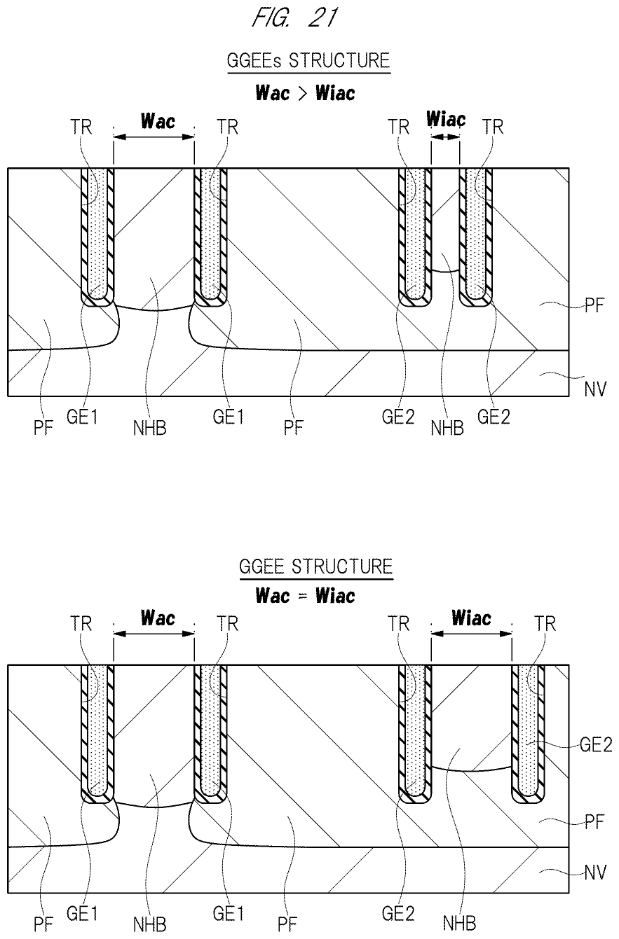

As shown in FIG. 21, in the GGEEs structure, a distance Wiac between the pair of trenches TR of the inactive cell IAC is smaller than a distance Wac between the pair of trenches TR of the active cell AC. In other words, the distance Wiac between the side surface SS6 and the side surface SS7 is smaller than the distance Wac between the side surface SS2 and the side surface SS3. In contrast, in the GGEE structure, the distance Wiac is the same as the distance Wac.

In the technique described in the first embodiment, as the distance Wiac becomes larger, it is more difficult to bring the two floating regions PF between the pair of trenches TR of the inactive cell IAC into contact with each other. However, with use of the technique described in the second embodiment, even if the distance Wiac is large as in the GGEE structure, it is possible to bring the two floating regions PF into contact with each other more positively.

### Third Embodiment

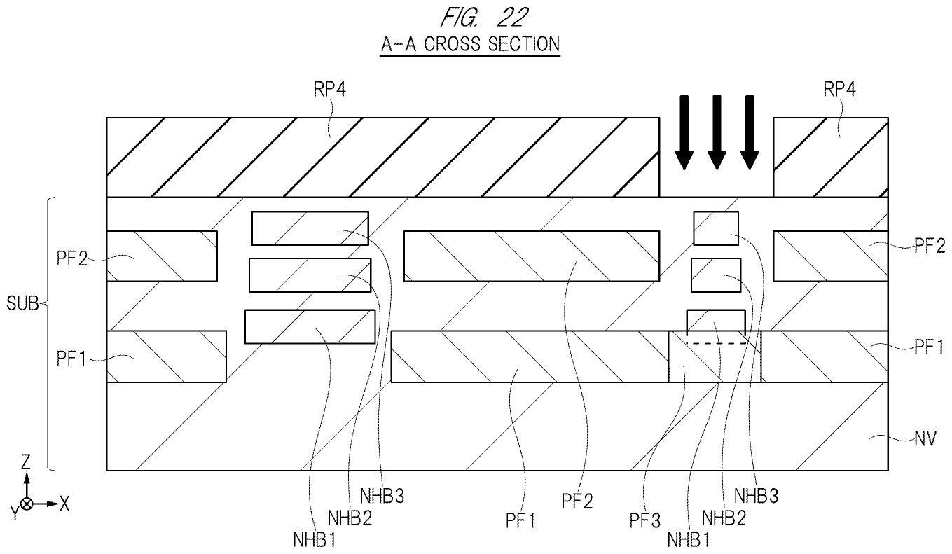

With reference to FIG. 22, a semiconductor device 100 according to the third embodiment and a method of manufacturing the same will be described below. Note that, in the following description, a difference from the first embodiment and the second embodiment will mainly be described, and overlapping description with the first embodiment and the second embodiment will be omitted.

In the third embodiment, as in the second embodiment, the manufacturing process for the floating region PF is designed such that a channel length of the parasitic PMOS transistor of the inactive cell IAC is more positively shorter. A final structure of the third embodiment is substantially the same as that of FIG. 17 in the second embodiment, overlapping description thereof will be omitted. Also in the third embodiment, the distance Diac described in FIG. 4 is shorter than that in the first embodiment.

With reference to FIG. 22, the manufacturing process for such floating region PF will be described below. The manufacturing process in FIG. 22 is carried out before the heat treatment in FIG. 10.

First, the two rounds of p-type ion implantation that has been described in FIG. 9 result in formation of the ion implantation layers PF1 and PF2. Before and after the formation of these ion implantation layers PF1 and PF2, the manufacturing process in FIG. 22 is carried out.

As shown in FIG. 22, first, over the upper surface of the semiconductor substrate SUB, the resist pattern RP4 is formed. The resist pattern RP4 has a pattern for opening positions at which the hole barrier region NHB (ion implantation layers NHB1 to NHB3) is to be formed. Next, with the resist pattern RP4 as a mask, the p-type ion implantation is carried out to the semiconductor substrate SUB from the upper surface of the semiconductor substrate SUB. As a result, the ion implantation layer PF3 is to be formed in the semiconductor substrate SUB. Then, the ashing treatment is carried out to remove the resist pattern RP4.

The ion implantation layer PF3 is formed at such a position as to overlap with a position at which the hole barrier region NHB (ion implantation layer NHB1 to NHB3) is formed, in plan view. In other words, the ion implantation layer PF3 is formed in the semiconductor substrate SUB between the two ion implantation layers PF1.

Note that the p-type ion implantation for the ion implantation layer PF3 is carried out under a condition in which boron (B) is implanted as an ion species at an energy of 1250 keV and in a dose amount of 1.25×10¹³/cm².

Thereafter, the trenches TR are formed, and the heat treatment described in FIG. 10 is carried out, whereby the impurities (B) contained in each of the ion implantation layers PF1 to PF3 are diffused to form the p-type floating region PF and the impurities (P) contained in each of the ion implantation layers NHB1 to NHB3 are diffused to form the n-type hole barrier region NHB.

Thus, the ion implantation layer PF3 is preliminarily formed at a position corresponding to a portion between the pair of trenches TR of the inactive cell IAC, so that the same advantage as those in the second embodiment can be achieved also in the third embodiment.

In addition, from a perspective of bringing the two floating regions PF into positive contact with each other, the third embodiment is more excellent than the first embodiment. However, in the third embodiment, the resist pattern RP4 is required, and accordingly, it is possible to reduce increase in manufacturing costs in the first embodiment than those in the third embodiment.

In addition, the technique in the third embodiment is effective in the GGEEs structure as in the second embodiment, and more effective in the GGEE structure. Specifically, as described in FIG. 21, in a case in which the distance Wiac is large like the GGEE structure, it is possible to bring the two floating regions PF into contact with each other more positively.

In the foregoing, the present invention has been concretely described based on the embodiments. However, the present invention is not limited to the foregoing embodiments, and various modifications and alterations can be made within the scope of the present invention.

What is claimed is:

1. A semiconductor device comprising:
a semiconductor substrate of a first conductivity type having an upper surface and a lower surface;
a first trench, a second trench, a third trench, and a fourth trench which are formed in the semiconductor substrate on the upper surface side of the semiconductor substrate;
a first gate electrode formed in the first trench with a first gate insulating film interposed between the first gate electrode and the first trench;
a second gate electrode formed in the second trench with a second gate insulating film interposed between the second gate electrode and the second trench;
a third gate electrode formed in the third trench with a third gate insulating film interposed between the third gate electrode and the third trench;
a fourth gate electrode formed in the fourth trench with a fourth gate insulating film interposed between the fourth gate electrode and the fourth trench;
a first hole barrier region of the first conductivity type formed in the semiconductor substrate between the first trench and the second trench on the upper surface side of the semiconductor substrate;
a first base region of a second conductivity type which is an opposite conductivity type to the first conductivity type, the first base region being formed in the first hole barrier region;
an emitter region of the first conductivity type formed in the first base region;
a second hole barrier region of the first conductivity type formed in the semiconductor substrate between the third trench and the fourth trench on the upper surface side of the semiconductor substrate;
a second base region of the second conductivity type formed in the second hole barrier region; and
a first floating region of the second conductivity type formed in the semiconductor substrate between the second trench and the third trench on the upper surface side of the semiconductor substrate,
wherein the first floating region covers a second bottom surface of the second trench, and covers a third bottom surface of the third trench so as to reach the semiconductor substrate between the third trench and the fourth trench, and
wherein a first distance between the second base region and the first floating region is smaller than a second distance between the first base region and the first floating region.

2. The semiconductor device according to claim 1,
wherein an impurity concentration of the second hole barrier region at a first portion in a vicinity of a boundary between the first floating region and the second hole barrier region in the second hole barrier region is lower than an impurity concentration of the first hole barrier region at a same depth as the first portion.

3. The semiconductor device according to claim 1,
wherein the first trench has a first side surface, a second side surface that is opposed to the first side surface, and a first bottom surface connecting the first side surface to the second side surface,
wherein the second trench has a third side surface, a fourth side surface that is opposed to the third side surface, and the second bottom surface connecting the third side surface to the fourth side surface,
wherein the third trench has a fifth side surface, a sixth side surface that is opposed to the fifth side surface, and the third bottom surface connecting the fifth side surface to the sixth side surface,
wherein the fourth trench has a seventh side surface, an eighth side surface that is opposed to the seventh side surface, and a fourth bottom surface connecting the seventh side surface to the eighth side surface,
wherein the first trench and the second trench are provided to be spaced from each other such that the second side surface and the third side surface are adjacent to each other,
wherein the third trench and the fourth trench are provided to be spaced from each other such that the sixth side surface and the seventh side surface are adjacent to each other,
wherein the first floating region is formed in the semiconductor substrate between the fourth side surface and the fifth side surface, and covers the third bottom surface so as to extend beyond the sixth side surface,
wherein the second distance is a distance along the third side surface, and
wherein the first distance is a distance along the sixth side surface.

4. The semiconductor device according to claim 3, further comprising:
a second floating region of the second conductivity type formed in the semiconductor substrate on the eighth side surface side, on the upper surface side of the semiconductor substrate; and
a third floating region of the second conductivity type formed in the semiconductor substrate on the first side surface side, on the upper surface side of the semiconductor substrate,
wherein the third floating region covers the first bottom surface,
wherein the second floating region covers the fourth bottom surface so as to extend beyond the seventh side surface,
wherein the first floating region and the third floating region are spaced apart from each other, and
wherein the first floating region and the second floating region are in contact with each other.

5. The semiconductor device according to claim 4,
wherein a distance between the sixth side surface and the seventh side surface is shorter than a distance between the second side surface and the third side surface.

6. The semiconductor device according to claim 4,
wherein a distance between the sixth side surface and the seventh side surface is same as a distance between the second side surface and the third side surface.

7. The semiconductor device according to claim 1, further comprising:
an interlayer insulating film formed over the upper surface of the semiconductor substrate so as to cover the first trench, the second trench, the third trench, and the fourth trench;
a gate wiring and an emitter electrode formed on the interlayer insulating film;
a collector region of the second conductivity type formed in the semiconductor substrate on the lower surface side of the semiconductor substrate; and
a collector electrode formed under the lower surface of the semiconductor substrate,
wherein the first gate electrode is electrically connected to the gate wiring,
wherein the emitter region, the first base region, the second gate electrode, and the second base region are electrically connected to the emitter electrode, and
wherein the collector region is electrically connected to the collector electrode.

8. A method of manufacturing a semiconductor device, the method comprising:
(a) preparing a semiconductor substrate of a first conductivity type having an upper surface and a lower surface;
(b) forming a first hole barrier region of the first conductivity type and a second hole barrier region of the first conductivity type in the semiconductor substrate, on the upper surface side of the semiconductor substrate;
(c) forming a first floating region of a second conductivity type which is an opposite conductivity type to the first conductivity type, in the semiconductor substrate, on the upper surface side of the semiconductor substrate;
(d) forming a first trench, a second trench, a third trench, and a fourth trench in the semiconductor substrate, on the upper surface side of the semiconductor substrate;
(e) after the (d), forming a first gate insulating film in the first trench, a second gate insulating film in the second trench, a third gate insulating film in the third trench, and a fourth gate insulating film in the fourth trench;
(f) after the (e), forming a first gate electrode in the first trench with the first gate insulating film interposed between the first gate electrode and the first trench, a second gate electrode in the second trench with the second gate insulating film interposed between the second gate electrode and the second trench, a third gate electrode in the third trench with the third gate insulating film interposed between the third gate electrode and the third trench, and a fourth gate electrode in the fourth trench with the fourth gate insulating film interposed between the fourth gate electrode and the fourth trench;
(g) after the (f), forming a first base region of the second conductivity type in the first hole barrier region, and a second base region of the second conductivity type in the second hole barrier region; and
(h) after the (g), forming an emitter region of the first conductivity type in the first base region,
wherein the first trench has a first side surface, a second side surface that is opposed to the first side surface, and a first bottom surface connecting the first side surface to the second side surface,
wherein the second trench has a third side surface, a fourth side surface that is opposed to the third side surface, and a second bottom surface connecting the third side surface to the fourth side surface,
wherein the third trench has a fifth side surface, a sixth side surface that is opposed to the fifth side surface, and a third bottom surface connecting the fifth side surface to the sixth side surface,
wherein the fourth trench has a seventh side surface, an eighth side surface that is opposed to the seventh side surface, and a fourth bottom surface connecting the seventh side surface to the eighth side surface,
wherein the first trench and the second trench are provided to be spaced apart from each other such that the second side surface and the third side surface are adjacent to each other,
wherein the third trench and the fourth trench are provided to be spaced apart from each other such that the sixth side surface and the seventh side surface are adjacent to each other,
wherein the first hole barrier region is formed in the semiconductor substrate between the second side surface and the third side surface,
wherein the second hole barrier region is formed in the semiconductor substrate between the sixth side surface and the seventh side surface,
wherein the first floating region is formed in the semiconductor substrate between the fourth side surface and the fifth side surface, covers the second bottom surface, and covers the third bottom surface so as to extend beyond the sixth side surface, and
wherein a first distance between the second base region and the first floating region is shorter than a second distance between the first base region and the first floating region.

9. The method of manufacturing a semiconductor device according to claim 8,
wherein the second distance is a distance along the third side surface, and
wherein the first distance is a distance along the sixth side surface.

10. The method of manufacturing a semiconductor device according to claim 8,
wherein, in the (c), a second floating region of the second conductivity type is formed in the semiconductor substrate on the eighth side surface side, and a third floating region of the second conductivity type is formed in the semiconductor substrate on the first side surface side,
wherein the third floating region covers the first bottom surface,
wherein the second floating region covers the fourth bottom surface so as to extend beyond the seventh side surface,
wherein the first floating region and the third floating region are spaced apart from each other, and
wherein the first floating region and the second floating region are in contact with each other.

11. The method of manufacturing a semiconductor device according to claim 10,
wherein the (c) includes:
(c1) forming a first resist pattern over the upper surface of the semiconductor substrate;
(c2) with the first resist pattern as a mask, carrying out first ion implantation from the upper surface side of the semiconductor substrate, thereby forming a first ion implantation layer, a second ion implantation layer, and a third ion implantation layer in the semiconductor substrate;
(c3) with the first resist pattern as a mask, carrying out second ion implantation from the upper surface side of the semiconductor substrate, thereby forming a fourth ion implantation layer in the semiconductor substrate at such a position as to overlap with the first ion implantation layer, in plan view, forming a fifth ion implantation layer in the semiconductor substrate at such a position as to overlap with the second ion implantation layer, in plan view, and forming a sixth ion implantation layer in the semiconductor substrate at such a position as to overlap with the third ion implantation layer, in plan view;
(c4) after the (c2) and the (c3), removing the first resist pattern; and
(c5) after the (c4), carrying out a first heat treatment to the semiconductor substrate, whereby impurities contained in each of the first ion implantation layer and the fourth ion implantation layer are diffused to form the first floating region, impurities contained in each of the second ion implantation layer and the fifth ion implantation layer are diffused to form the second floating region, and impurities contained in each of the third ion implantation layer and the sixth ion implantation layer are diffused to form the third floating region,
wherein an energy of the first ion implantation is larger than an energy of the second ion implantation, and
wherein the (d) is carried out between the (c4) and the (c5).

12. The method of manufacturing a semiconductor device according to claim 11,
wherein the (c) further includes:
(c6) between the (c4) and the (d), carrying out a second heat treatment to the semiconductor substrate, thereby activating the impurities contained in each of the first ion implantation layer, the second ion implantation layer, the third ion implantation layer, the fourth ion implantation layer, the fifth ion implantation layer, and the sixth ion implantation layer, and
wherein the first heat treatment is carried out under a condition at a higher temperature and for a longer period of time than those in the second heat treatment.

13. The method of manufacturing a semiconductor device according to claim 11,
wherein the (c) further includes, before the (c5):
(c7) forming a second resist pattern over the upper surface of the semiconductor substrate;
(c8) with the second resist pattern as a mask, carrying out third ion implantation from the upper surface side of the semiconductor substrate, thereby forming a seventh ion implantation layer in the semiconductor substrate between the first ion implantation layer and the second ion implantation layer; and
(c9) after the (c8), removing the second resist pattern,
wherein, in the (c5), the impurities contained in each of the first ion implantation layer, the fourth ion implantation layer, and the seventh ion implantation layer are activated to form the first floating region, and the impurities contained in each of the second ion implantation layer, the fifth ion implantation layer, and the seventh ion implantation layer are activated to form the second floating region,
wherein an energy of the third ion implantation is larger than an energy of the second ion implantation, and
wherein the (d) is carried out between the (c9) and the (c5).

14. The method of manufacturing a semiconductor device according to claim 10,
wherein the (c) further includes:
(c10) forming a first resist pattern over the upper surface of the semiconductor substrate;
(c11) with the first resist pattern as a mask, carrying out first ion implantation from the upper surface side of the semiconductor substrate, thereby forming a first ion implantation layer and a third ion implantation layer in the semiconductor substrate;
(c12) after the (c11), removing the first resist pattern;
(c13) forming a second resist pattern on the upper surface of the semiconductor substrate;
(c14) with the second resist pattern as a mask, carrying out second ion implantation from the upper surface side of the semiconductor substrate, thereby forming a fourth ion implantation layer and a fifth ion implantation layer in the semiconductor substrate at such a position as to overlap with the first ion implantation layer, in plan view, and forming a sixth ion implantation layer in the semiconductor substrate at such a position as to overlap with the third ion implantation layer, in plan view;
(c15) after the (c14), removing the second resist pattern; and
(c16) after the (c12) and the (c15), carrying out a first heat treatment to the semiconductor substrate, whereby impurities contained in each of the first ion implantation layer and the fourth ion implantation layer are diffused to form the first floating region, impurities contained in each of the first ion implantation layer and the fifth ion implantation layer are diffused to form the second floating region, and impurities contained in each of the third ion implantation layer and the sixth ion implantation layer are diffused to form the third floating region,
wherein the first ion implantation layer is formed also at such a position as to overlap with a position at which the second hole barrier region is formed, in plan view,
wherein an energy of the first ion implantation is larger than an energy of the second ion implantation, and
wherein the (d) is carried out after the (c12) and the (c15) and before the (c16).

15. The method of manufacturing a semiconductor device according to claim 14,
wherein the (c) further includes:
(c17) after the (c12) and the (c15) and before the (d), carrying out a second heat treatment to the semiconductor substrate, thereby activating the impurities contained in each of the first ion implantation layer, the third ion implantation layer, the fourth ion implantation layer, the fifth ion implantation layer, and the sixth ion implantation layer, and
wherein the first heat treatment is carried out under a condition at a higher temperature and for a longer period of time than those in the second heat treatment.

16. The method of manufacturing a semiconductor device according to claim 11,
wherein a distance between the sixth side surface and the seventh side surface is shorter than a distance between the second side surface and the third side surface.

17. The method of manufacturing a semiconductor device according to claim 13,
wherein a distance between the sixth side surface and the seventh side surface is same as a distance between the second side surface and the third side surface.

18. The method of manufacturing a semiconductor device according to claim 14,
wherein a distance between the sixth side surface and the seventh side surface is same as a distance between the second side surface and the third side surface.

19. The method of manufacturing a semiconductor device according to claim 8, the method further comprising:
(i) after the (h), forming an interlayer insulating film over the upper surface of the semiconductor substrate so as to cover the first trench, the second trench, the third trench, and the fourth trench;
(j) after the (i), forming a gate wiring and an emitter electrode on the interlayer insulating film;
(k) after the (j), forming a collector region of the second conductivity type in the semiconductor substrate on the lower surface side of the semiconductor substrate; and
(l) after the (k), forming a collector electrode under the lower surface of the semiconductor substrate,
wherein the first gate electrode is electrically connected to the gate wiring,
wherein the emitter region, the first base region, the second gate electrode, and the second base region are electrically connected to the emitter electrode, and
wherein the collector region is electrically connected to the collector electrode.
